(19) United States
(12) Patent Application Publication
(10) Pub. No.: US 2025/0328170 A1
(43) Pub. Date: Oct. 23, 2025

(54) DISPLAY DEVICE

(71) Applicant: Samsung Display Co., LTD., Yongin-si (KR)

(72) Inventors: TAE-CHANG KIM, Yongin-si (KR); SANGHYO PARK, Yongin-si (KR); HYERI WANG, Yongin-si (KR); CHANHUI HAN, Yongin-si (KR); HAEJIN KIM, Yongin-si (KR); BYOUNGSU LEE, Yongin-si (KR)

(21) Appl. No.: 19/061,646

(22) Filed: Feb. 24, 2025

(30) Foreign Application Priority Data
Apr. 23, 2024 (KR) 10-2024-0053720

(51) Int. Cl. G06F 1/16

(52) U.S. Cl. CPC G06F 1/1656; G06F 1/1652

(57) ABSTRACT

A display device includes a display assembly including a first region and a second region, and an extending module under the first region. The second region is under the first region in an inserting state, and a portion thereof is on a same plane as the first region in a spreading state. The extending module includes a first part coupled to an end of the second region, a second part at a side of the first part, a fixing pin including a body part passing through the first part or the second part, and a head part at an end of the body part, and an elastic body interposed between the first part or the second part, and the head part. A moving distance of the first part is substantially equal to a moving distance of the second part when changing from the inserting state to the spreading state.

This application claims priority to Korean Patent Application No. 10-2024-0053720, filed on Apr. 23, 2024, and all the benefits accruing therefrom under 35 U.S.C. § 119, the content of which in its entirety is herein incorporated by reference.

### BACKGROUND

### (1) Field

Embodiments of the disclosure described herein relate to a display device.

### (2) Description of the Related Art

In general, an electronic device, such as a smart phone, a digital camera, a notebook computer, a navigation system, or a smart television, which provides an image to a user, includes a display device to display the image. The display device generates an image and provides the image to the user through a display screen.

Recently, as the technology of the display device is developed, various types of display devices have been developed. For example, a flexible display device has been developed to slide and to roll out to expand to an outside of a case. The flexible display device variously changed in shape may have improved portability, thereby improving convenience of use.

### SUMMARY

Embodiments of the disclosure provide a display device improved in surface quality.

According to an embodiment of the disclosure, a display device includes a display assembly including a first region on a plane defined by a first direction and a second direction crossing the first direction, and a second region extending from the first region, where the second region disposed under the first region in an inserting state, and a portion of the second region is on a same plane as the first region in a spreading state, and an extending module disposed under the first region. In such an embodiment, the extending module includes a first part coupled to an end of the second region and extending in the second direction, a second part disposed at a side of the first part in the first direction and extending in the second direction, a fixing pin including a body part extending in the first direction and passing through the first part or the second part, and a head part disposed on an end of the body part, and an elastic body disposed between the first part or the second part, through which the body part passes, and the head part. In such an embodiment, a moving distance of the first part in the first direction is substantially equal to a moving distance of the second part in the first direction when a state of the display assembly is changed from the inserting state to the spreading state.

According to an embodiment of the disclosure, a display device includes a display assembly including a first region on a plane defined by a first direction and a second direction crossing the first direction, and a second region extending from the first region, where the second region is disposed under the first region in an inserting state, and a portion of the second region is on a same plane as the first region in a spreading state, and an extending module disposed under the first region. In such an embodiment, the extending module includes a first part coupled to an end of the second region and extending in the second direction, a second part disposed at a side of the first part in the first direction and extending in the second direction, a fixing pin including a body part extending in the first direction and passing through the first part or the second part, and a head part disposed on an end of the body part, and an elastic body disposed between the first part or the second part, through which the body part passes, and the head part, and a moving distance of the first part in the first direction is greater than a moving distance of the second part in the first direction when a state of the display assembly is changed from the inserting state to the spreading state.

### BRIEF DESCRIPTION OF THE DRAWINGS

The above and other features of embodiments of the disclosure will become apparent by describing in detail embodiments thereof with reference to the accompanying drawings.

FIG. 1 is an electronic device including a display device according to an embodiment of the disclosure.

FIG. 2A is a view illustrating the display device illustrated in FIG. 1.

FIG. 2B is a view illustrating a spreading mode of the display device illustrated in FIG. 2A.

FIG. 3 is an exploded perspective view of the display device illustrated in FIG. 2B.

FIG. 4 is a cross-sectional view taken along line I-I′ illustrated in FIG. 3.′

FIG. 5A is a view illustrating a display assembly illustrated in FIG. 3.

FIG. 5B is a view illustrating support bars illustrated in FIG. 5A.

FIG. 5C is a view illustrating a display assembly according to an embodiment of the disclosure.

FIG. 5D is an enlarged plan view illustrating a first region illustrated in FIG. 5C.

FIG. 6 is a cross-sectional view illustrating the display module illustrated in FIG. 5A.

FIG. 7 is a cross-sectional view illustrating a display panel illustrated in FIG. 6.

FIGS. 8A to 8C are views illustrating a driving unit of an extending module.

FIGS. 9A and 9B are views illustrating a connecting part according to an embodiment of the disclosure.

FIG. 9C is a view illustrating an elastic body according to an embodiment.

FIG. 9D is a view illustrating a connecting part according to an embodiment.

FIGS. 9E and 9F are views illustrating the coupling of a connecting part and a driving unit.

FIG. 10A is a view illustrating a moving plate according to an embodiment of the disclosure.

FIGS. 10B and 10C are views illustrating the coupling between a driving unit and a moving plate.

FIG. 11A is a perspective view illustrating the coupling of the support bars and the extending module.

FIG. 11B is a cross-sectional view taken along line II-II′ illustrated in FIG. 11A.

FIG. 12A is a perspective view illustrating the spreading mode of the extending module illustrated in FIG. 11A.

FIG. 12B is a cross-sectional view taken along line III-III′ illustrated in FIG. 12A.

FIG. 12C is a view illustrating a moving distance of a moving plate and a tensile bar.

FIG. 13A to 13E are view illustrating a display device according to a comparative example.

FIGS. 14A to 14E are views illustrating a mechanism for improving a furrow according to an embodiment of the disclosure.

FIGS. 15A and 15B are views illustrating the height of the furrow of the display module DM depending on the elastic modulus of the elastic body illustrated in FIG. 14A.

FIGS. 16A to 16E are cross-sectional views of a display device according to an embodiment of the disclosure.

FIGS. 17A and 17B are views illustrating a connecting part according to an embodiment.

FIGS. 18A to 18C are views illustrating the operation of a connecting part illustrated in FIG. 17A.

FIGS. 19A to 19C are views illustrating a display device according to an embodiment of the disclosure.

FIGS. 20A and 20B are views illustrating a driving unit according to an embodiment of the disclosure.

FIGS. 21A and 21B are views illustrating a driving unit according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the specification, the expression that a first component (or region, layer, part, portion, etc.) is “connected to”, or “coupled to” a second component means that the first component is directly on, connected to, or coupled to the second component or means that a third component is interposed therebetween.

The same reference numeral will be assigned to the same component. In addition, in drawings, thicknesses, proportions, and dimensions of components may be exaggerated to describe the technical features effectively.

Although the terms “first”, “second”, etc. may be used to describe various components, the components should not be construed as being limited by the terms. The terms are only used to distinguish one component from another component. For example, without departing from the scope and spirit of the invention, a first component may be referred to as a second component, and similarly, the second component may be referred to as the first component.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

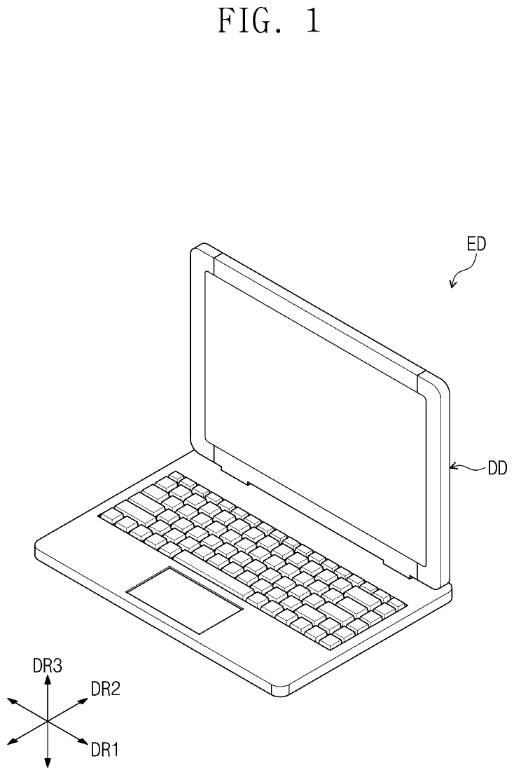

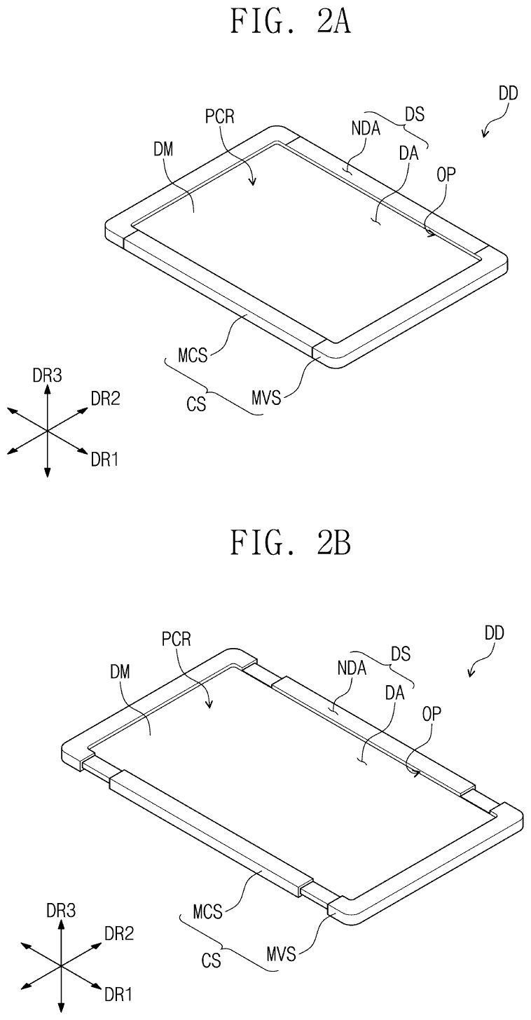

FIG. 1 is an electronic device ED including a display device DD according to an embodiment of the disclosure. FIG. 2A is a view illustrating a display device DD illustrated in FIG. 1. FIG. 2B is a view illustrating a spreading mode of the display device illustrated in FIG. 2A.

For the convenience of illustration and description, a keyboard and a mouse pad illustrated in FIG. 1 are omitted from FIGS. 2A and 2B. In addition, as illustrated in FIGS. 2A and 2B, a front surface of the display device DD faces up.

Referring to FIG. 1, an embodiment of the electronic device ED may be a device activated in response to an electrical signal. In an embodiment, as shown in FIG. 1, the electronic device ED may be in the form of a laptop computer, but not being limited thereto. The electronic device ED may include various embodiments. In an embodiment, for example, the electronic device ED may be any of various types of electronic device including a display screen, such as a smart watch, a tablet computer, a smartphone, a computer, a smart television, or a navigation.

Referring to FIG. 2A, for example, the display device DD may have the shape of a rectangle having a longer side extending in a first direction DR1 and a short side extending in a second direction DR2 in a plan view, that is, when viewed in a thickness direction thereto. Here, a third direction DR3 may be the thickness direction and may be perpendicular to the first direction DR1 and the second direction DR2. However, the disclosure is not limited thereto, and the display device DD may have various shapes such as a circle or a polygon.

The front surface of the display device DD may be defined as a display surface DS, and the display surface DS may be a plane defined in the first direction DR1 and the second direction DR2. An image or a video generated from the display device DD through the display surface DS may be provided to a user.

The display surface DS may include a display region DA and a non-display region NDA around the display region DA. The display region DA is a region to display an image and the non-display region NDA is a region not to display the image. The non-display region NDA may surround the display region DA in a plan view.

Referring to FIGS. 2A and 2B, FIG. 2A illustrates the display device DD in an inserting mode (or an inserting state), and FIG. 2B illustrates the display device DD in a spreading mode (or a spreading state).

The display device DD may include a display assembly PCR and a case CS to receive the display assembly PCR. The display assembly PCR may include a display module DM. The display module DM may be exposed to an outside through an opening OP defined at an upper portion of the case CS. In such an embodiment, a top surface of the display module DM may be the display surface DS.

The case CS may include a main case MCS and a plurality of moving cases MVS. The main case MCS and the moving cases MVS are coupled to each other to receive the display assembly PCR. The moving cases MVS may be coupled to the main case MCS to move in the first direction DR1.

As illustrated in FIG. 2A, the area of the display surface DS, which is exposed to the outside, of the display assembly PCR may be set to the minimum area when the moving case MVS is closest to the main case MCS. Such a state of the display device DD may be defined as the inserting mode (or the inserting state).

The area of the display surface DS may be adjusted, as the moving cases MVS move. In an embodiment, for example, the moving cases MVS may move in the first direction DR1 by external force applied thereto by the user. As illustrated in FIG. 2B, as the moving cases MVS move, the area of the display surface DS, which is exposed to the outside, of the display assembly PCR may be increased, and the user may view the image through a larger screen.

The state of the display device DD, in which the area of the display surface DS, which is exposed to the outside, of the display assembly PCR is increased larger than the area of the display surface DS illustrated in FIG. 2A, may be defined as the spreading mode (or the spreading state). In such an embodiment, the state of the display device DD, in which the area of the display surface DS, which is exposed to the outside, of the display assembly PCR is not increased any more, may be defined as a maximum spreading mode (or a maximum spreading state).

In an embodiment, as described above, the moving cases MVS move in the first direction DR1 by the external force applied thereto by the user, but the disclosure is not limited thereto. In another embodiment, for example, the moving cases MVS may move by an internal motor and internal gear of the case CS.

Although not illustrated, in the inserting mode, a portion, which is not exposed to the outside, of the display module DM may be provided or disposed in the case CS, in addition to the display surface DS exposed through the opening OP.

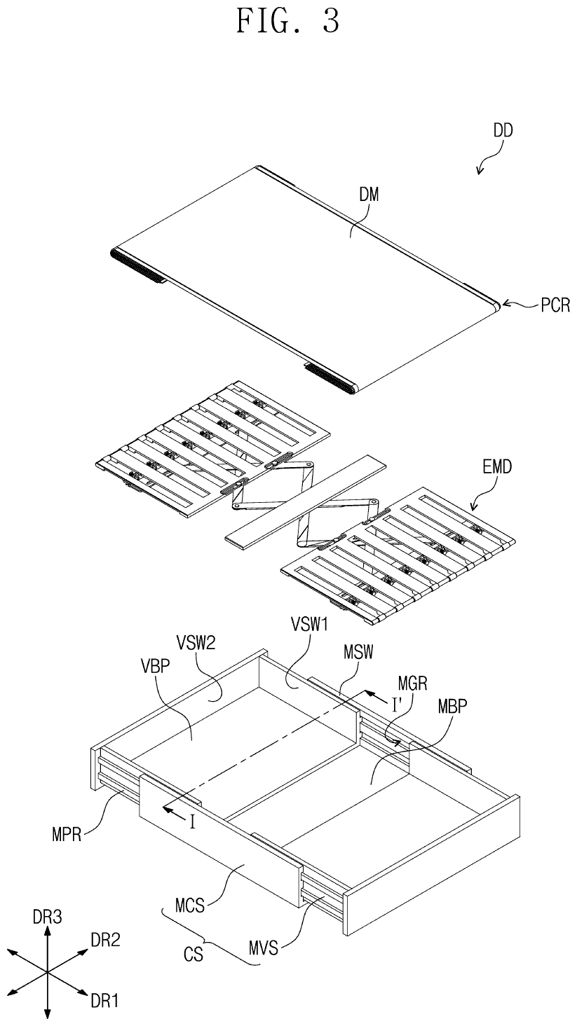

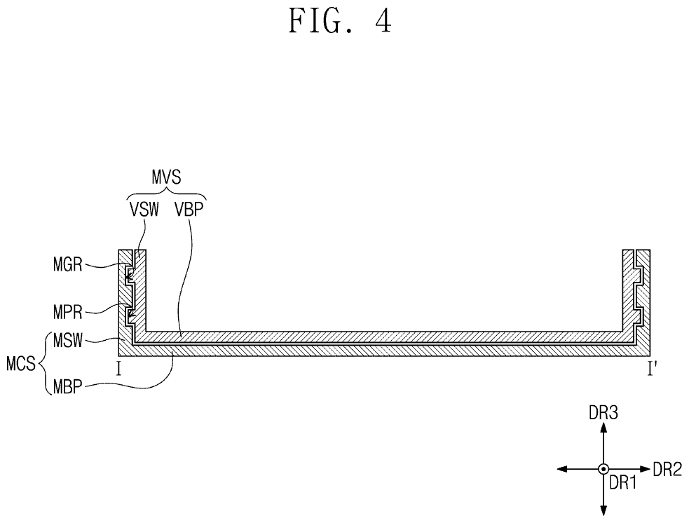

FIG. 3 is an exploded perspective view of the display device DD illustrated in FIG. 2B. FIG. 4 is a cross-sectional view taken along line I-I′ illustrated in FIG. 3.

Particularly, FIG. 3 is an exploded perspective view of the display device DD in the spreading mode. However, the maximum spreading mode is not illustrated in FIG. 3.

Referring to FIGS. 3 and 4, an embodiment of the display device DD may include the display assembly PCR, an extending module EMD, and the case CS. The case CS may include the main case MCS and the plurality of moving cases MVS.

The main case MCS may include a main bottom part MBP and a plurality of main sidewall parts MSW. The main bottom part MBP may be on a plane defined by the first direction DR1 and the second direction DR2.

The main sidewall parts MSW may be disposed at sides, which are opposite to each other in the second direction DR2, of the main bottom part MBP. The main sidewall parts MSW may extend in the third direction DR3 from the sides, which are opposite to each other in the second direction DR2, of the main bottom part MBP. The main sidewall parts MSW may face each other in the second direction DR2.

The main sidewall parts MSW may be parallel to a plane defined by the first direction DR1 and the third direction DR3, and may extend to be longer in the first direction DR, rather than the third direction DR3. The main sidewall parts MSW facing each other may be symmetrical to each other in the second direction DR2.

In an embodiment, as shown in FIG. 4, main guide grooves MGR may be defined in inner surfaces of the main sidewall parts MSW facing each other. The main guide grooves MGR may extend in the first direction DR1. Two pairs of main guide grooves MGR may face each other in the second direction DR2. Each pair of main guide grooves MGR may be arranged in the third direction DR3.

The moving cases MVS may be arranged in the first direction DR1. The moving cases MVS may be disposed on the main bottom part MBP. The moving cases MVS may be disposed between the main sidewall parts MSW.

Each of the moving cases MVS may include a moving bottom part VBP, a plurality of first moving sidewall parts VSW1, and a second moving sidewall part VSW2. Hereinafter, although one moving case MVS of the plurality of moving cases MVS will be mainly described for the convenience of explanation, another moving case MVS of the plurality of moving cases MVS may have a configuration substantially the same as a configuration of the one moving case MVS.

The moving bottom part VBP may be parallel to a plane defined by the first direction DR1 and the second direction DR2. The moving bottom part VBP may be disposed on the main bottom part MBP.

The first moving sidewall parts VSW1 may extend in a third direction DR3 from the sides, which are opposite to each other in the second direction DR2, of the moving bottom part VBP. The first moving sidewall parts VSW1 may face each other in the second direction DR2. The first moving sidewall parts VSW1 may be disposed between inner surfaces of the main sidewall parts MSW facing each other in the second direction DR2.

The first moving sidewall parts VSW1 may have a plane defined by the first direction DR1 and the third direction DR3, and may extend to be longer in the first direction DR1, rather than the third direction DR3. The first moving sidewall parts VSW1 facing each other are symmetrical to each other in the second direction DR2.

Moving protruding parts MPR may be disposed on outer side surfaces of the first moving sidewall parts VSW1. The moving protruding parts MPR may extend in the first direction DR1. A plurality of moving protruding parts may be disposed on one outer side surface, and may be arranged in the third direction DR3.

Each of the moving protruding parts MPR may be disposed in a corresponding main guide groove MGR of the main guide grooves MGR. When viewed in the first direction DR1, the shape of the outer surface of the moving protruding parts MPR may correspond to the shape of the main guide grooves MGR.

The moving protruding parts MPR may reciprocate in the first direction DR1 along the main guide grooves MGR. Accordingly, the moving cases MVS may move in the first direction DR1 with respect to the main case MCS. As the moving cases MVS move in the first direction DR1, an area in which the main bottom part MBP overlaps the moving bottom part VBP, may be varied.

The second moving sidewall part VSW2 may be disposed at one end, which is positioned farther away from the central region of the main bottom part MBP, of opposite ends of the first moving sidewall part VSW1. The second moving sidewall parts VSW2 may have a plane defined by the second direction DR2 and the third direction DR3, and may extend to be longer in the second direction DR2, rather than the third direction DR3.

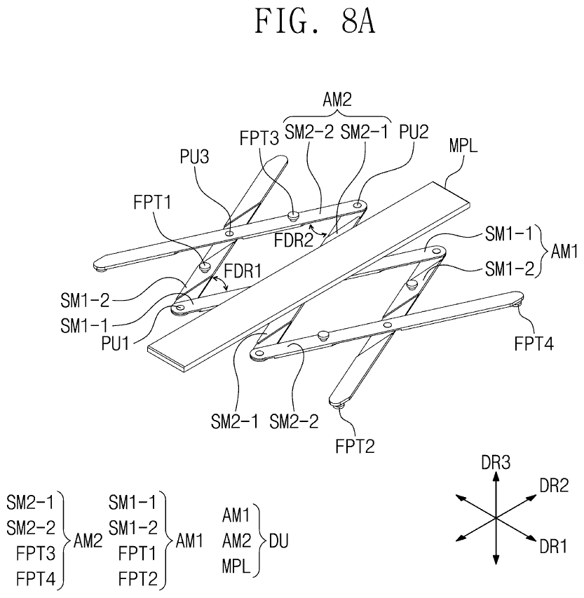

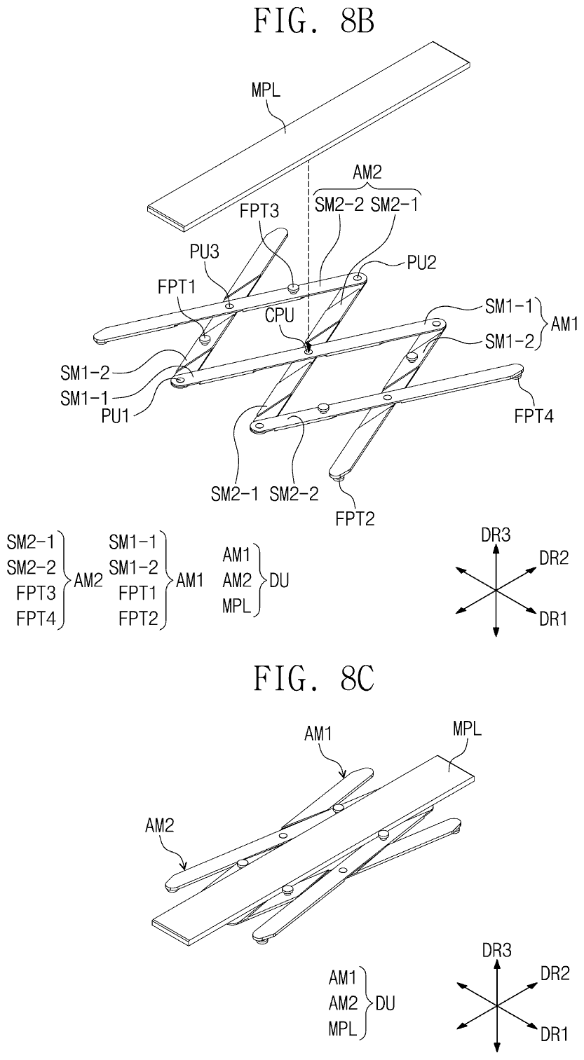

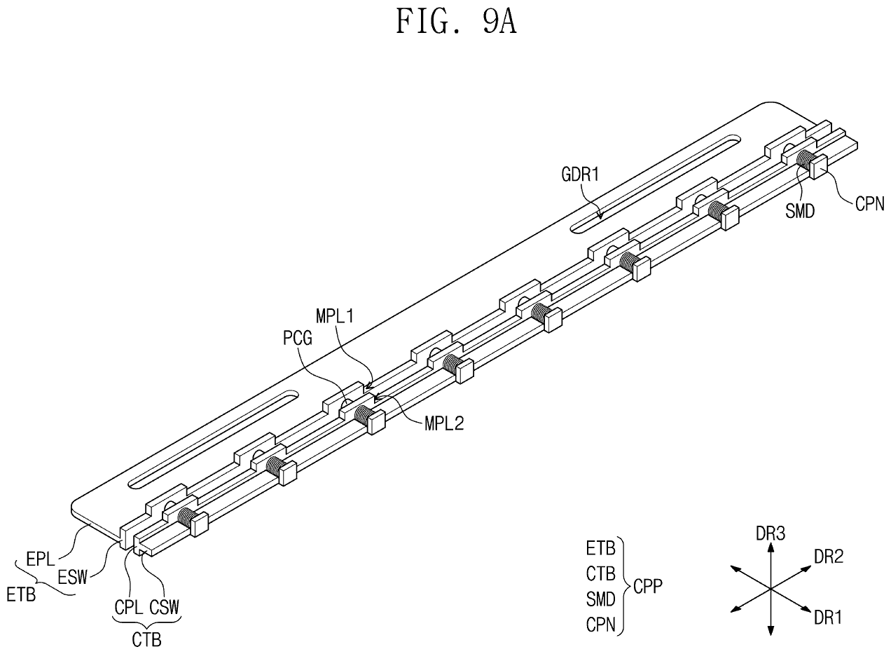

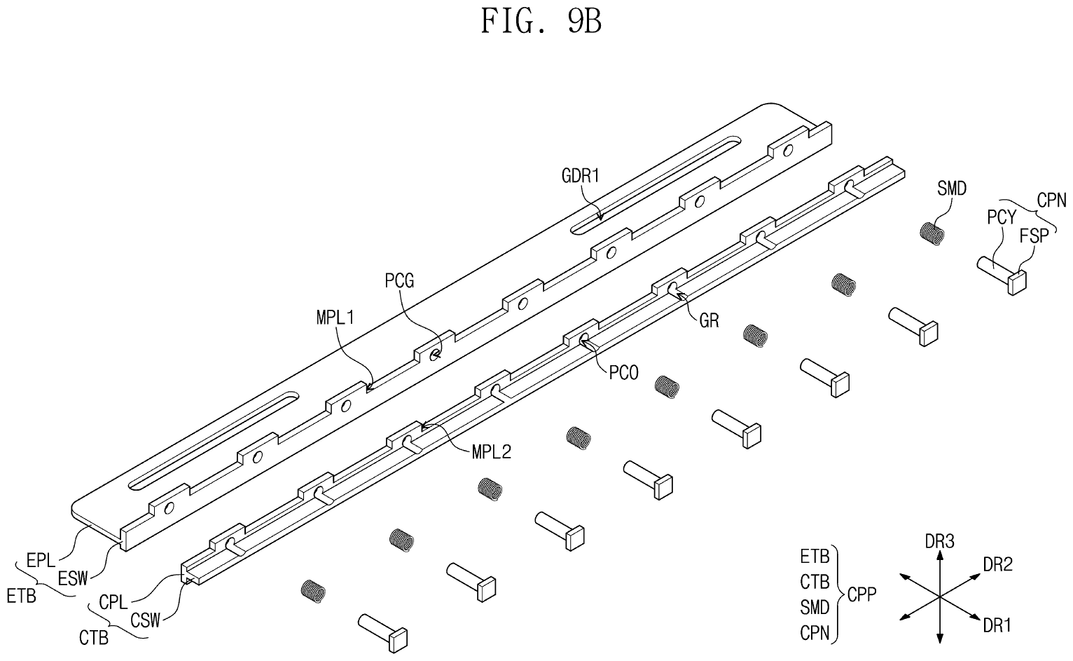

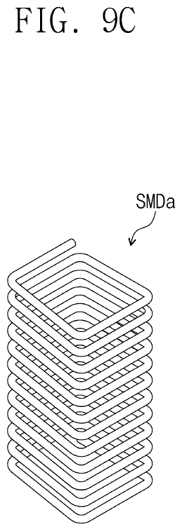

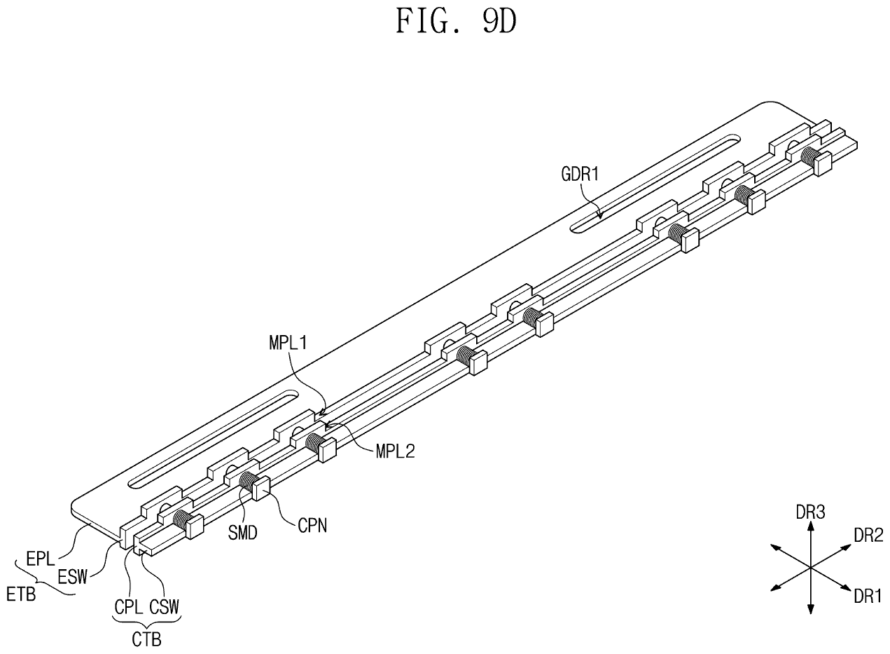

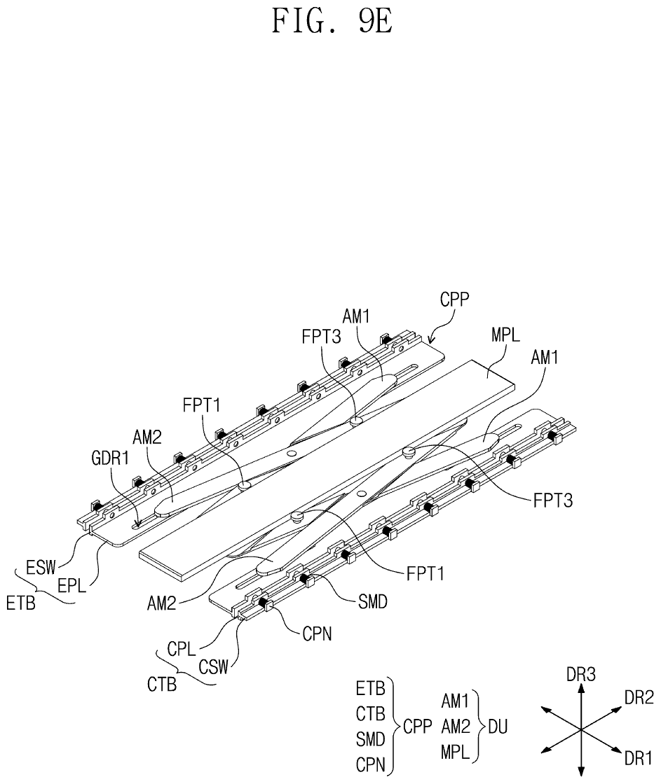

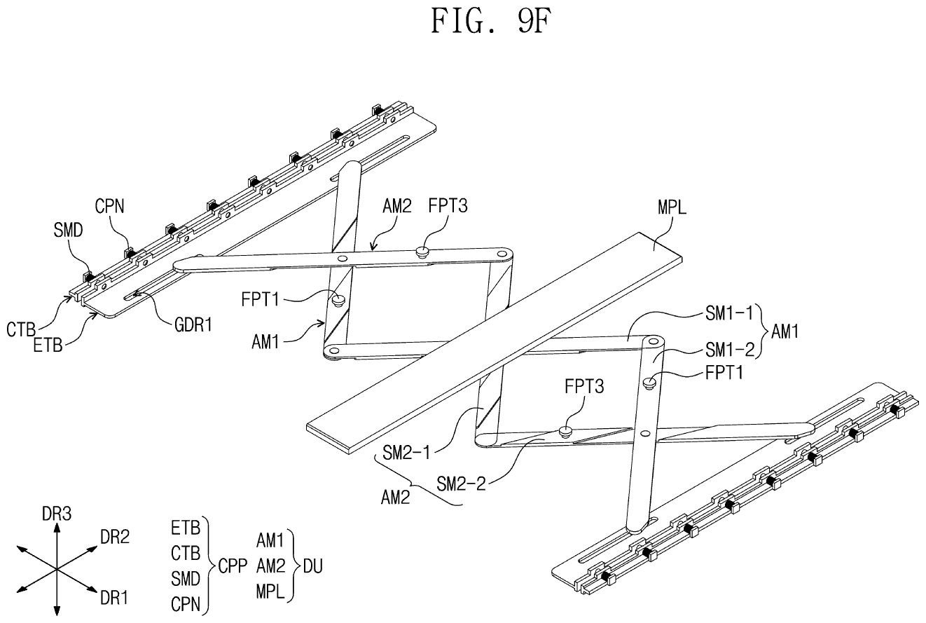

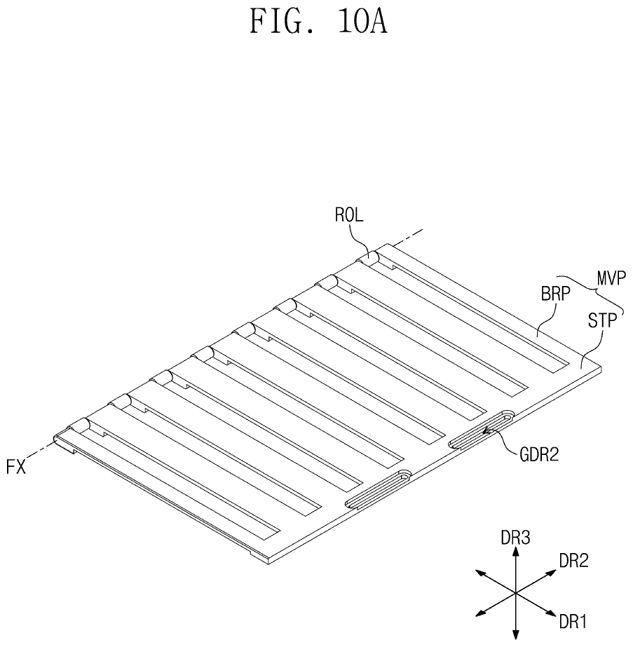

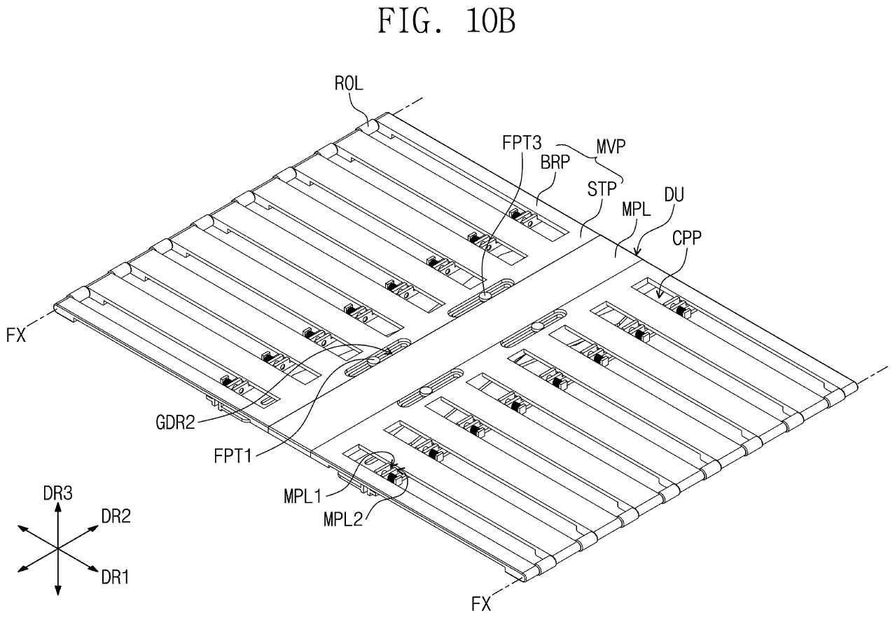

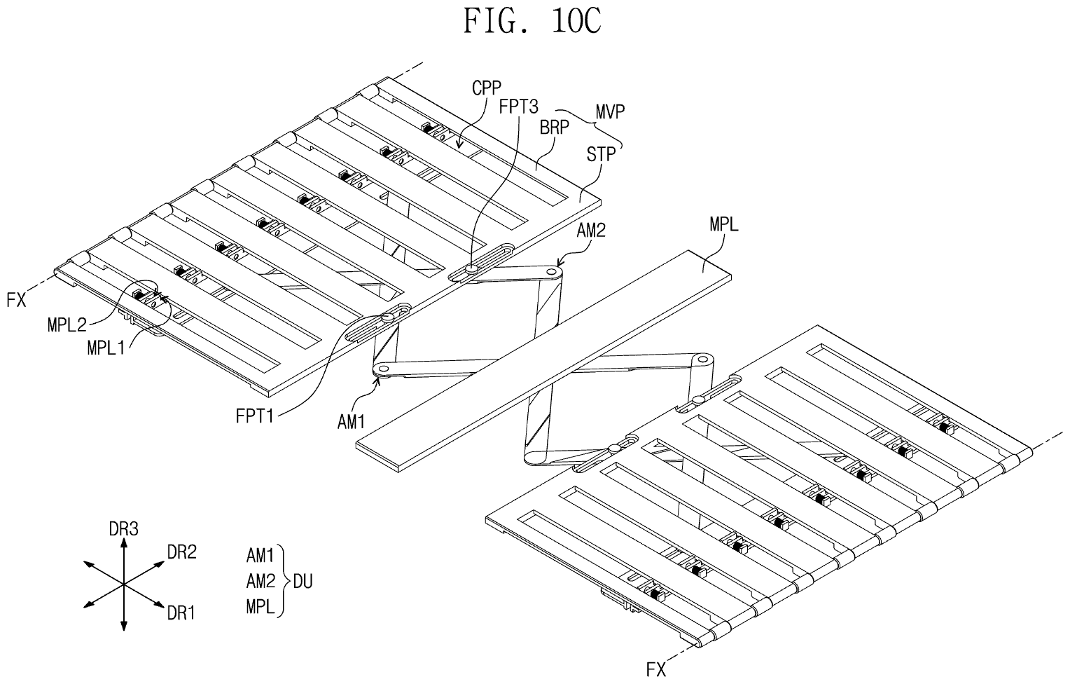

The extending module EMD may include a driving unit DU (see FIG. 8A), a plurality of connecting parts CPP (see FIG. 9A), moving plates MVP (see FIG. 10A), and a plurality of rollers ROL (see FIG. 10A). The extending module EMD may be disposed or received in the case CS. The extending module EMD may be extended and shrunken in the first direction DR1. Although not illustrated, the extending module EMD may be coupled to the moving cases MVS. Accordingly, when the moving cases MVS move in the first direction DR1, the extending module EMD may be extended. The detailed features of the extending module EMD will be described later.

The display assembly PCR may be disposed on the extending module EMD. The display assembly PCR may be disposed or received in the case CS. Sides, which are opposite to each other in the first direction DR1, of the display assembly PCR may have a curved shape convex outward. A portion, which has the convex curved shape, of the display assembly PCR, may be received in the case CS, such that the portion is not exposed to the outside.

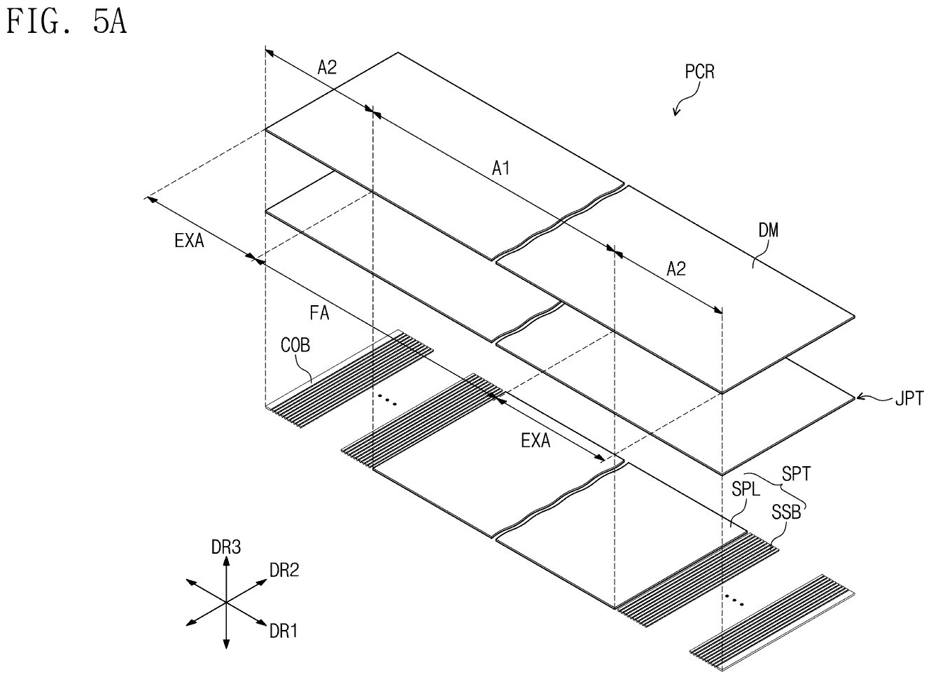

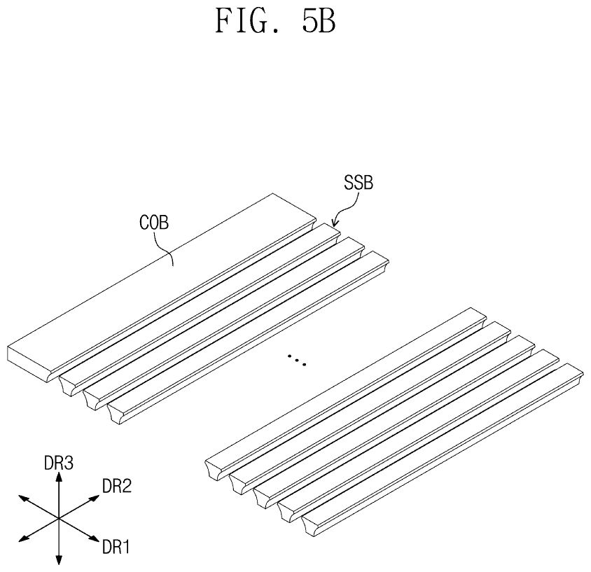

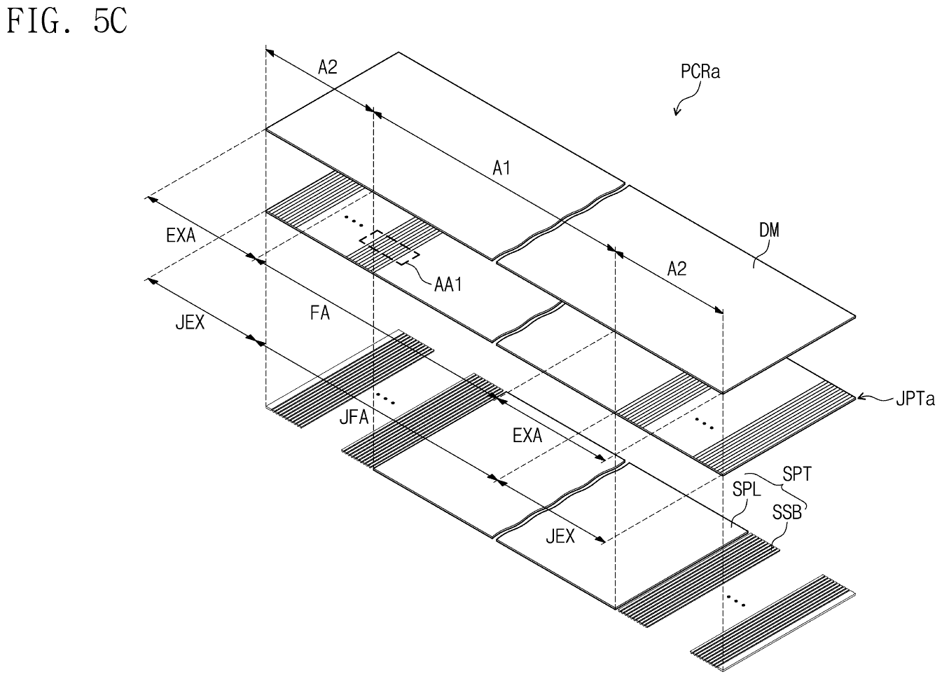

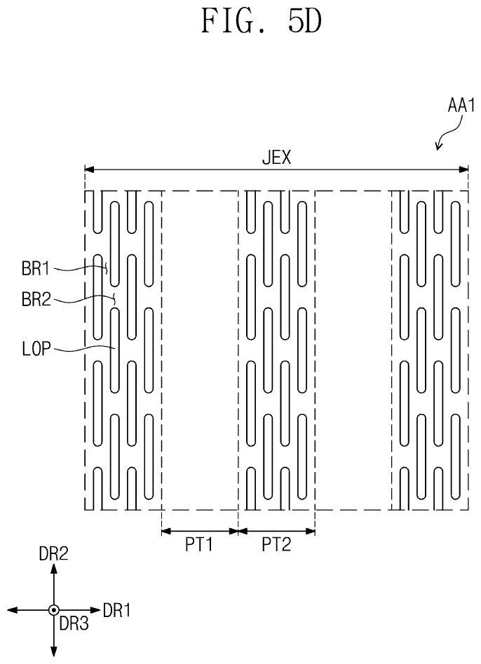

FIG. 5A is a view illustrating the display assembly PCR illustrated in FIG. 3. FIG. 5B is a view illustrating support bars SSB illustrated in FIG. 5A. FIG. 5C is a view illustrating a display assembly PCRa according to another embodiment of the disclosure. FIG. 5D is an enlarged plan view illustrating a first region AA1 illustrated in FIG. 5C.

Particularly, FIGS. 5A and 5C are perspective views illustrating the display assemblies PCR and PCRa fully spread. FIG. 5B is a perspective view illustrating the support bars SSB fully spread. The display assemblies PCR and PCRa fully spread refers to that the display assemblies PCR and PCRa are spread further from the display assemblies PCR and PCRa in the maximum spreading mode. In other words, the display assemblies PCR and PCRa fully spread may refers to the display assemblies PCR and PCRa spread while being separated from the extending module EMD.

Although FIG. 5B illustrates only the support bars SSB disposed at the left side of a fixed plate SPL of FIG. 5A for convenience of illustration, the support bars SSB disposed at the right side of the fixed plate SPL may have substantially the same structure as the support bars SSB disposed at the left side of the fixed plate SPL of FIG. 5A.

Referring to FIG. 5A, the display assembly PCR may include a first region A1 and second regions A2 extending in the first direction DR1 from sides, which are opposite to each other, of the first region A1.

The first region A1 may be exposed to the outside of the case CS of FIG. 3, both in the inserting mode of FIG. 2A and the spreading mode of FIG. 2B. The first region A1 may be parallel to a plane defined by the first direction DR1 and the second direction DR2.

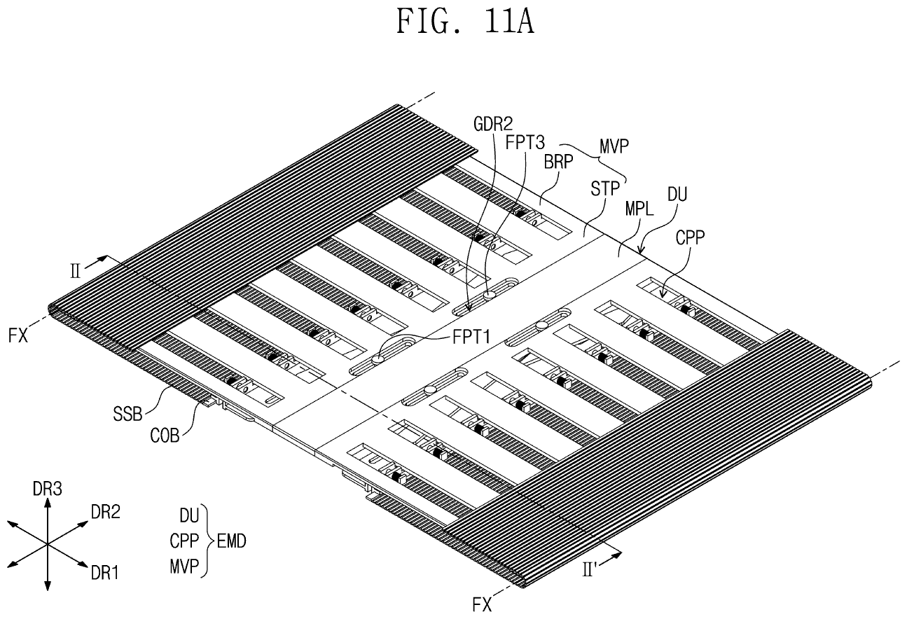

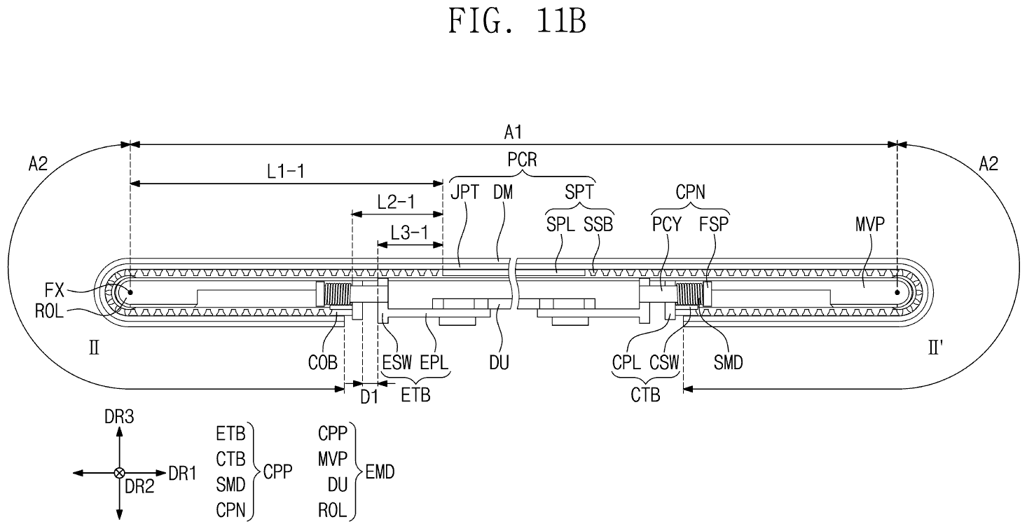

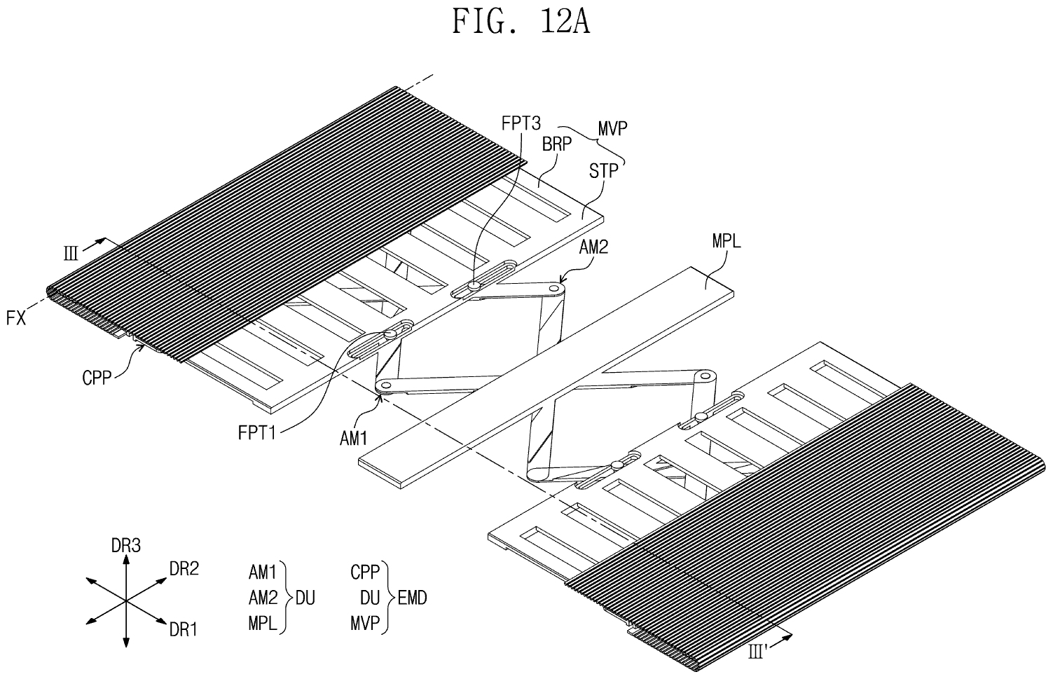

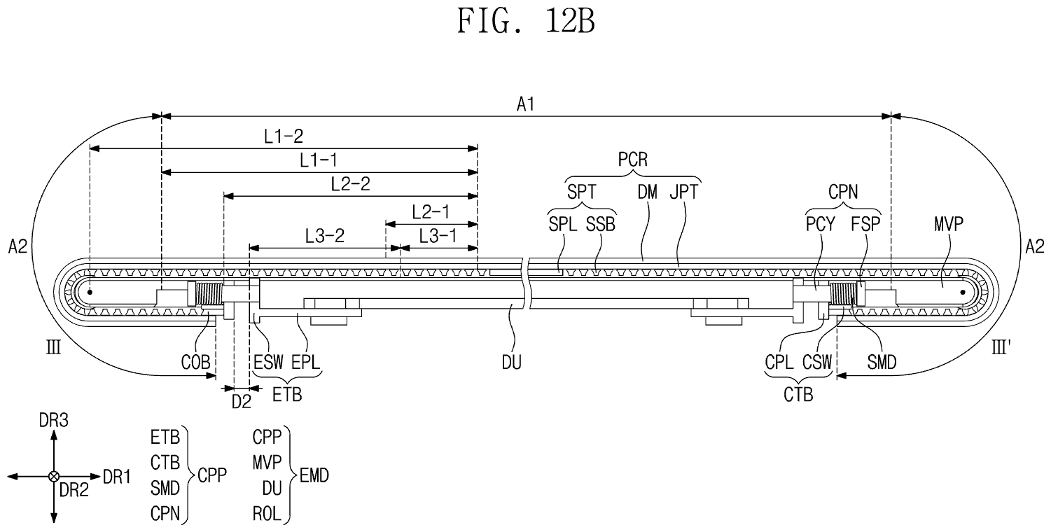

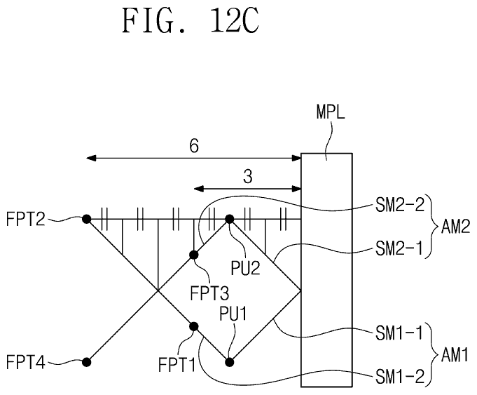

The area of the second regions A2 exposed to the outside of the case CS may be varied depending on the inserting mode and the spreading mode of the display device DD. When the display device DD is in the spreading mode, a portion of the second regions A2 may be exposed to the outside and may be aligned in line with sides, which are opposite to each other in the first direction, of the first region A1. As illustrated in FIG. 3, when the display device DD is received in the case CS, a portion of the second regions A2 may be disposed under the first region A1. The features thereof will be described in greater detail with reference to FIGS. 11A to 12B.

The display assembly PCR may include the display module DM, a coupling part JPT, and a support plate SPT. In an embodiment, the display module DM may a rectangular shape having longer sides extending in the first direction DR1 and shorter sides extending in the second direction DR2.

The display module DM may include a fixed part FA and extending parts EXA extending from the fixed part FA. The fixed part FA may overlap the first region A1. Each of the extending parts EXA may overlap a corresponding second region A2 of the second regions A2. The fixed part FA may be exposed to the outside of the case CS, both in the inserting mode and the spreading mode of the display device DD. The region exposed to the outside of the case CS may be varied depending on the inserting mode and the spreading mode of the display device DD. When the display device DD is in the spreading mode, a portion of the extending parts EXA may be exposed to the outside and aligned in line with the sides of the fixed part FA opposite to each other in the first direction DR1.

When the display device DD is in the inserting mode, a portion of the extending parts EXA may be disposed under the fixed part FA.

Referring to FIGS. 5A and 5B, the support plate S′PT may be disposed under the display module DM. The support plate SPT may include the fixed plate SPL and the support bars SSB. The fixed plate SPL may be on a plane defined by the first direction DR1 and the second direction DR2. The fixed plate SPL may overlap the fixed part FA. The fixed plate SPL may be disposed under the fixed part FA to support the fixed part FA.

The support bars SSB may be disposed under the extending parts EXA. The support bars SSB may overlap with the extending parts EXA. The support bars SSB may be disposed at sides, which are opposite to each other in the first direction DR1, of the fixed plate SPL. The support bars SSB and the fixed plate SPL may be arranged in the first direction DR1.

The support bars SSB may be arranged in the first direction DR1 and may extend in the second direction DR2. A support bar SSB, which is spaced farthest away from the fixed plate SPL, (that is, an outermost support bar in the first direction DR1) of the plurality of support bars SSB may be defined as a coupling support bar COB. The coupling support bar COB may be coupled to the extending module EMD illustrated in FIG. 3. The coupling between the coupling support bar COB and the extending module EMD will be described in detail with reference to FIGS. 11B and 12B.

In an embodiment, the fixed plate SPL and the support bars SSB may include a metal material such as stainless steel (e.g., SUS 316), but the metal material of the fixed plate SPL and the support bars SSB is not limited thereto. In another embodiment, the fixed plate SPL and the support bars SSB may include a non-metallic material such as plastic.

The coupling part JPT may be disposed between the display module DM and the support plate SPT. The coupling part JPT may be parallel to a plane defined by the first direction DR1 and the second direction DR2, in the state that the coupling part JPT may be fully spread.

A flat top surface of the coupling part JPT may be provided on a bottom surface of the display module DM. Although not illustrated, an adhesive agent may be interposed between the coupling part JPT and the display module DM. The coupling part JPT may be bonded to the display module DM by the adhesive agent. The coupling part JPT may include polyimide, polycarbonate, urethane silicon, or polyethylene terephthalate. However, the coupling part JPT is not limited thereto, and may include metal. The detailed features thereof will be described with reference to FIGS. 5C and 5D.

The support plate SPT may be attached to the bottom surface of the coupling part JPT. Although not illustrated, the support plate SPT and the coupling part JPT may be bonded to each other by an adhesive agent. In a case where the coupling part JPT is omitted, the display module DM may be disposed on the support bars SSB. In this case, since the support bars SSB are spaced apart from each other, the display module DM may sag downward between the support bars SSB. Accordingly, the surface quality of the display module DM may be degraded.

In an embodiment, the coupling part JPT is interposed between the display module DM and the support plate SPT, such that the coupling part JPT may provide a flat surface to the display module DM. Accordingly, The display module DM may be effectively maintained in a flat state by the coupling part JPT.

Referring to FIGS. 5C and 5D, in an embodiment, a coupling part JPTa may include a metal material such as stainless steel (for example, SUS 316), but the metal material of the coupling part JPTa is not limited thereto.

The coupling part JPTa may include a fixed region JFA and extending regions JEX extending from the fixed region JFA. The fixed region JFA may overlap the fixed part FA. The extending regions JEX may overlap the extending parts EXA. The extending regions JEX may be disposed at sides, which are opposite to each other in the first direction DR1, of the fixed region JFA.

The extending regions JEX may include a plurality of first extending parts PT1 and a plurality of second extending parts PT2. The first extending parts PT1 and the second extending parts PT2 may be arranged in the first direction DR1 to be alternately arranged. The second extending parts PT2 may be interposed between the first extending parts PT1 adjacent to each other in the first direction DR1. The first extending parts PT1 may overlap the support bars SSB illustrated in FIG. 5B. The support bars SSB may be disposed on the bottom surface of the first extending parts PT1. The second extending parts PT2 may overlap the support bars SSB illustrated in FIG. 5B.

A plurality of openings LOP may be defined or formed in the second extending parts PT2. The openings OP may be arranged in the first direction DR1 and the second direction DR2. The openings LOP may further extend in the second direction DR2 rather than the first Direction DR1. The openings LOP, which are disposed in a h-th column, may be offset from the openings LOP disposed in a (h+1)-th column, when viewed in the sequence of the first direction DR1. The column may correspond to the second direction DR2. Here, ‘h’ is a natural number.

The second extending parts PT2 may include first branch parts BR1 and second branch parts BR2. The first branch parts BR1 may be interposed between the openings LOP adjacent to each other in the first direction DR1. The second branch parts BR2 may be interposed between the openings LP adjacent to each other in the second direction DR2. The first branch parts BR1 may extend in the second direction DR2, and the second branch parts BR2 may extend in the first direction DR1. The openings LOP may be defined by the first and second branch parts BR1 and BR2

In such an embodiment, the openings LOP are provided, such that the stiffness of extending regions JEX may be reduced and the flexibility of the extending regions JEX may be increased. Accordingly, as illustrated in FIG. 3, when the sides, which are opposite to each other in the first direction DR1, of the display module DM have the curved surface convex outward, the extending region JEX may be easily bent.

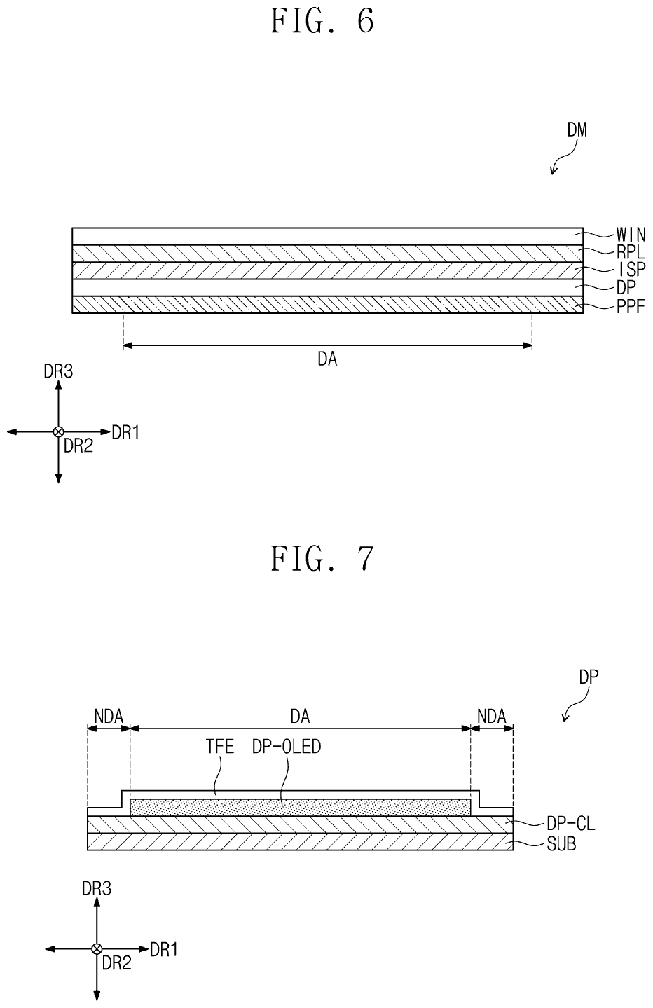

FIG. 6 is a cross-sectional view illustrating the display module illustrated in FIG. 5A.

Referring to FIG. 6, an embodiment of the display module DM may include the display panel DP, the input sensing part ISP, an anti-reflective layer RPL, a window WIN, and a panel protecting film PPF.

The display panel DP may be a flexible display panel. According to an embodiment of the disclosure, the display panel DP may be an emissive-type display panel, but the disclosure is not limited thereto. In an embodiment, for example, the display panel DP may be an organic light emitting display panel or an inorganic light emitting display panel. A light emitting layer of the organic light emitting display layer may include an organic light emitting material. The light emitting layer of the inorganic light emitting display panel may include a quantum dot, or a quantum rod. Hereinafter, embodiments where the display panel DP is the organic light emitting display panel will be mainly described by way of example, but not being limited thereto.

The input sensing part ISP may be directly disposed on the display panel DP. The input sensing part ISP may include a plurality of sensing units (not illustrated) to sense an external input in a capacitive manner. In an embodiment, the input sensing part ISP may be directly formed on the display panel DP when manufacturing the display device DD. However, the disclosure is not limited thereto. In another embodiment, the input sensing part ISP is manufactured separately from the display panel DP, and may be attached to the display panel DP by the adhesive layer.

The anti-reflective layer RPL may be disposed on the input sensing part ISP. The anti-reflective layer RPL may be defined as a film to prevent external light from being reflected. The anti-reflective layer RPL may reduce the reflectance of external light incident from the top surface of the display device DD (see FIG. 1) toward the display panel DP. In an embodiment, for example, the anti-reflective layer RPL may include a plurality of color filters to display the same color as that of pixels of the display panel DP.

The color filters may filter the external light in the same color as the pixels. In this case, the external light may not be viewed by the user. However, the disclosure is not limited thereto. In an embodiment, for example, the anti-reflective layer RPL may include a phase retarder and/or a polarizer, to reduce the reflectance of the external light.

The window WIN may be disposed on the anti-reflective layer RPL. The window WIN may protect the display panel DP, the input sensing part ISP, and the anti-reflective layer RPL from external scratches and impacts.

The panel protecting film PPF may be disposed under the display panel DP. The panel protecting film PPF may protect a bottom surface of the display panel DP. The panel protecting film PPF may include a flexible plastic material such as Polyethyleneterephthalate (PET).

Although not illustrated, an adhesive layer may be interposed between the display panel DP and the panel protecting film PPF, and the display panel DP may be bonded to the panel protecting film PPF through the adhesive layer. Although not illustrated, the adhesive layer may be interposed between the window WIN and the anti-reflective layer RPL, and the window WIN and the anti-reflective layer RPL may be bonded to each other by the adhesive layer.

FIG. 7 is a cross-sectional view illustrating the display panel illustrated in FIG. 6.

Referring to FIG. 7, an embodiment of the display panel DP includes a substrate SUB, a circuit element layer DP-CL disposed on the substrate SUB, a display element layer DP-OLED disposed on the circuit element layer DP-CL, and a thin film encapsulating layer TFE disposed on the display element layer DP-OLED.

The substrate SUB may include a display region DA and a non-display region NDA around the display region DA. The substrate SUB may include a flexible plastic material such as polyimide (PI). The display element layer DP-OLED is disposed in the display region DA.

A plurality of pixels may be disposed on the pixel element layer DP-CL and the display element layer DP-OLED. Each of pixels may include transistors disposed in the circuit element layer DP-CL and a light emitting device disposed on the display element layer DP-OLED and connected to the transistors.

The thin film encapsulating layer TFE may be disposed on the circuit element layer DP-CL to cover the display element layer DP-OLED. The thin film encapsulating layer TFE may protect the pixels from moisture, oxygen, and external foreign substances.

FIGS. 8A to 8C are perspective view illustrating the driving unit DU of the extending module EMD.

Particularly, FIGS. 8A and 8B illustrate the driving unit DU in the spreading mode, and FIG. 8C illustrates the driving unit DU in the inserting mode.

Referring to FIGS. 8A to 8C, an embodiment of the extending module EMD of FIG. 3 may include the driving unit DU. The driving unit D may be extended and shrunken in the first direction DR1. The driving unit DU may include a main plate MPL, and a first arm AM1 and a second arm AM2 which are coupled to the main plate MPL. The main plate MPL may have a rectangular shape having a shorter side extending in the first direction DR1 and a longer side extending in the second direction DR2 in a plan view or when viewed in the third direction DR3.

The first arm AM1 and the second arm AM2 may be coupled to a bottom surface of the main plate MPL. The first arm AM1 and the second arm AM2 may have shapes symmetrical to each other about the second direction DR2, and may have a foldable bellows (pantograph) structure designed to be unfolded or folded in the first direction.

The first arm AM1 may include a first first joint unit (hereinafter, will be referred to as “(1-1)-th joint unit”) SM1-1 and a plurality of second first joint units (hereinafter, will be referred to as “(1-2)-th joint units”) SM1-2. The (1-1)-th joint unit SM1-1 may be pivotably coupled onto the bottom surface of the main plate MPL. The (1-1)-th joint unit SM1-1 may be pivotable about a center pin CPU to be described later. The (1-1)-th joint unit SM1-1 may pivot about a rotation axis parallel to the third direction DR3.

The (1-2)-th joint units SM1-2 may be coupled to opposite sides of the (1-1)-th joint unit SM1-1. The (1-2)-th joint units SM1-2 may be pivotably coupled to the (1-1)-th joint unit SM1-1 through a plurality of first pins PU1. The (1-2)-th joint units SM1-2 may be pivoted at a specific first angle FDR1 with respect to the (1-1)-th joint unit SM1-1.

Since the (1-1)-th joint unit SM1-1 and the (1-2)-th joint units SM1-2 are coupled in a folding manner and are unfolded or folded in the first direction DR1, the first arm AM1 may be expanded or contracted in the first direction DR1.

The first arm AM1 may include a plurality of first pin protruding parts FPT1 and a plurality of second pin protruding parts FPT2. The first pin protruding parts FPT1 may be disposed on a top surface of the (1-2)-th joint units SM1-2. The first pin protruding parts FPT1 may be interposed between the first pins PU1 and third pins PU3 to be described below.

The second pin protruding parts FPT2 may be disposed on a bottom surface of the (1-2)-th joint units SM1-2. The second pin protruding parts FPT2 may be disposed to be adjacent to each other at one sides of the (2-2)-th joint units SM1-2. The one sides of the (1-2)-th joint units SM1-2 may be defined as sides disposed away from the first fins PU1. The first pin protruding parts FPT1 may be closer to the first pins PU1 rather than the second pin protruding parts FPT2.

The second arm AM2 may include a first second joint unit (hereinafter, will be referred to as “(2-1)-th joint unit”) SM2-1 and a plurality of second second joint units (hereinafter, will be referred to as “(2-2)-th joint units”) SM2-2. The (2-1)-th joint unit SM2-1 may be coupled onto the bottom surface of the main plate MPL to pivot about a rotation axis parallel to the third direction DR3. The (2-1)-th joint unit SM2-1 may be pivotable about the central pin CPU.

The (2-2)-th joint units SM2-2 may be pivotably coupled to the (2-1)-th joint unit SM2-1 through a plurality of second pins PU2. The (2-2)-th joint units SM2-2 may be pivoted at a specific second angle FDR2 with respect to the (2-1)-th joint unit SM2-1. The size of the second angle FDR2 may be substantially the same as the size of the first angle FDR1.

Since the (2-1)-th joint unit SM2-1 and the (2-2)-th joint units SM2-2 are coupled in a folding manner and are unfolded or folded in the first direction DR1, the second arm AM2 may be expanded or contracted in the first direction DR1.

The second arm AM2 may include a plurality of third pin protruding parts FPT3 and a plurality of fourth pin protruding parts FPT4. The third pin protruding parts FPT3 may be disposed on a top surface of the (2-2)-th joint units SM2-2. The third pin protruding parts FPT3 may be interposed between the second pins PU2 and third pins PU3 to be described below.

The fourth pin protruding parts FPT4 may be disposed on a bottom surface of the (2-2)-th joint units SM2-2. The fourth pin protruding parts FPT4 may be disposed to be adjacent to each other at one sides of the (2-2)-th joint units SM2-2. The one sides of the (2-2)-th joint units SM2-2 may be defined as sides disposed away from the second fins PU2. The third pin protruding parts FPT3 may be closer to the second pins PU2, rather than the fourth pin protruding parts FPT4.

The first arm AM1 and the second arm AM2 may be coupled to each other. The (1-1)-th joint units SM1-1 and the (1-2)-th joint units SM2-1 may be coupled to each other through the central pin CPU under the main plate MPL. The pivoting direction of the (2-1)-th joint unit SM2-1 may be opposite to the (1-1)-th joint unit SM1-1. When the display device DD is changed to be in the spreading mode from the inserting mode, the (1-1)-th joint units SM1-1 may pivot clockwise about the rotation axis parallel to the third direction DR3, and the (2-1)-th joint units SM2-1 may rotate counterclockwise about the rotation axis parallel to the third direction DR3.

The (1-2)-th joint units SM2-1 may be coupled to a relevant (2-2)-th joint units SM2-2 of the (2-2)-th joint units SM2-2. The (1-2)-th joint units SM2-1 and the (2-2)-th joint units SM2-2 may be coupled to each other through the third pins PU3. When the display device DD is changed to be in the inserting mode from the spreading mode, the (1-2)-th joint units SM2-1 and the (2-2)-th joint units SM2-2 may rotate in opposite directions.

When the driving unit DU is expanded, the distance from opposite sides of the main plate MPL to the first and third pin protruding units FPT1 and FPT3 in the first direction DR1 may be increased. When the driving unit DU is expanded, the distance from opposite sides of the main plate MPL to the first and fourth pin protruding units FPT2 and FPT4 in the first direction DR1 may be increased. The detailed features thereof will be described with reference to FIG. 12.

FIGS. 9A and 9B are views illustrating a connecting part CPP according to an embodiment of the disclosure. FIG. 9C is a view illustrating an elastic body SMDa according to an embodiment. FIG. 9D is a view illustrating a connecting part CPPa according to an embodiment. FIGS. 9E and 9F are views illustrating the coupling between the connecting part CPP and the driving unit DU.

Particularly, FIGS. 9A to 9F are perspective views.

Particularly, FIG. 9B is an exploded perspective view of the connecting part CPP illustrated in FIG. 9A.

Particularly, FIG. 9E is a view illustrating the driving unit DU and the connecting part CPP in the inserting mode, and FIG. 9F is a view the driving unit DU and the connecting part CPP in the spreading mode.

Referring FIGS. 9A and 9B, an embodiment of the extending module EMD of FIG. 3 may further include a plurality of connecting parts CPP. In an embodiment, for example, the extending module EM may include two connecting parts CPP, but the number of the connecting parts CPP is not limited thereto. Hereinafter, one connecting parts CPP of two connecting parts CPP will be mainly described for the convenience of description.

The connecting part CPP may include a plurality of parts distinguished from each other. The connecting part CPP may include a first part CTB coupled to one end of the second region A2 (see FIG. 5A), and be provided with first openings PCO defined in the first part CTB, and a second part ETB disposed at one side of the first part CTB in the first direction DR1 while extending in the second direction DR2.

The connecting part CPP may include fixing pins CPN coupled to the first part CTB through the first opening PCO in the first direction DR1, and a plurality of elastic bodies SMD interposed between the fixing pins CPN and the first part CTB such that elasticity thereof varies. Hereinafter, the first part CTB may be referred to as a connecting bar CTB, and the second part ETB may be referred to as a tensile bar ETB.

The tensile bar ETB may extend in the second direction DR2. In an embodiment, for example, when viewed in the second direction DR2, the tensile bar ETB may have the shape obtained by rotating ‘T’ at 90 degrees. According to an embodiment of the disclosure, the tensile bar ETB may include a part parallel to a plane defined in the second direction DR2 and the third direction DR3, and a part parallel to the plane defined by the first direction DR1 and the second direction DR2.

The tensile bar ETB may include a coupling plate EPL and an inserting plate ESW. The coupling plate EPL may be parallel to a plane defined by the first direction DR1 and the second direction DR2, and may extend to be longer in the second direction DR2 rather than the first direction DR1.

A plurality of first guide grooves GDR1 may be defined or formed in a coupling plate EPL. The first guide grooves GDR1 may be formed at one side of sides, which are opposite to each other in the first direction DR1, of the coupling plate EPL to be adjacent to each other. The one side of the sides, which are opposite to each other in the first direction DR1, of the coupling plate EPL may be defined as a side disposed away from the connecting bar CTB.

Each of the first guide grooves GDR1 may extend in the second direction DR2. The first guide grooves GDR1 may be arranged in the second direction DR2. In an embodiment, for example, two first guide grooves GDR1 be defined or formed in a coupling plate EPL as shown in FIGS. 9A to 9D, but the number of first guide grooves GDR1 is not limited thereto.

An inserting plate ESW may be disposed at an opposite side of the sides, which are opposite to each other in the first direction DR1, of the coupling plate EPL. The another side of the sides, which are opposite to each other in the first direction DR1, of the coupling plate EPL may be defined as a side closer to the connecting bar CTB. In an embodiment, for example, the coupling plate EPL and the inserting plate ESW may be integrally formed as a single unitary indivisible part.

The inserting plate ESW may be parallel to a plane defined by the second direction DR2 and the third direction DR3, and may extend in the second direction DR2. When viewed in the second direction DR2, a top surface and a bottom surface, which are opposite to each other in the third direction DR3, of the inserting plate ESW may protrude further than a top surface and a bottom surface of the coupling plate EPL, respectively.

A plurality of inserting grooves PCG may be formed in the inserting plate ESW. The inserting grooves PCG may be defined in one side of sides, which are opposite to each other in the first direction DR1, of the inserting plate ESW. In an embodiment, for example, when viewed in the first direction DR1, the inserting grooves PCG may have the shape of a circle. In an embodiment, for example, eight inserting grooves PCG be defined in the inserting plate ESW as shown in FIGS. 9A to 9D, but the number of the inserting grooves PCG is not limited thereto. The one side of the sides, which are opposite to each other in the first direction DR1, of the inserting plate ESW may be defined as a side closer to the connecting bar CTB.

The inserting grooves GDR1 may be arranged in the second direction DR2. In an embodiment, for example, the distance between the inserting grooves PCG adjacent to each other in the second direction DR2 may be uniform. However, the distance between the inserting grooves PCG adjacent to each other in the second direction DR2 may be not uniform. The detailed features thereof will be described with reference to FIG. 9D.

A plurality of first grooves MPL1 may be defined on the top surface of the inserting plate ESW. The first grooves MPL1 may be defined between the inserting grooves PCG adjacent to each other in the second direction DR2. The first grooves MPL1 may extend downward from the top surface of the inserting plate ESW. In an embodiment, the first grooves MPL1 may have a shape corresponding to a rectangular shape.

The tensile bar ETB and the connecting bar CTB may be arranged in the first direction DR1. The tensile bar ETB and the connecting bar CTB may be arranged to be spaced apart from each other by a specific distance in the first direction DR1. The connecting bar CTB may be disposed to be adjacent to the one side of sides, which are opposite to each other in the first direction DR1, of the inserting plate ESW.

The connecting bar CTB may extend in the second direction DR2. In an embodiment, for example, when viewed in the second direction DR2, the connecting bar CTB may have the shape obtained by rotating ‘T’ at 90 degrees. According to an embodiment of the disclosure, the connecting bar CTB may include a part parallel to a plane defined in the second direction DR2 and the third direction DR3, and a part parallel to the plane defined by the first direction DR1 and the second direction DR2.

The connecting bar CTB may include a connecting plate CSW and a through plate CPL. The connecting plate CSW may be parallel to a plane defined by the first direction DR1 and the second direction DR2, and may extend to be longer in the second direction DR2 rather than the first direction DR1.

The plurality of grooves GR may be defined in the top surface of a connecting plate CSW. The grooves GR may extend from one side of sides, which are opposite to each other in the first direction DR1, of the connecting plate CSW, from an opposite side of the connecting plate CSW. When viewed in the first direction DR1, the grooves GR may have the shape corresponding to a portion of a circle. According to another embodiment of the disclosure, the grooves GR may be omitted. The one side of sides, which are opposite to each other in the first direction DR1, of the connecting plate CSW may be defined as a side away from the inserting plate ESW in the first direction.

The through plate CPL may be disposed at an opposite side, which faces the inserting plate ESW in the first direction, of the sides of the connecting plate CSW. In an embodiment, for example, the connecting plate CSW and the through plate CPL may be integrally formed as a single unitary indivisible part.

The through plate CPL may extend in the second direction DR2. The length of the through plate CPL in the third direction DR3 may be longer than the length of the connecting plate CSW in the third direction DR3. When viewed in the second direction DR2, a top surface and a bottom surface, which are opposite to each other in the third direction DR3, of the through hole CSW may protrude from a top surface and a bottom surface of the connecting plate CSW.

The plurality of first openings PCO may be formed in the through plate CPL. The first openings PCO may be consecutively defined in the first direction DR1 together with grooves GR. In an embodiment, for example, when viewed in the first direction DR1, the first openings PCO may have the shape of a circle.

The first openings PCO may be arranged in the second direction DR2. For example, the distance between the first openings PCO adjacent to each other in the second direction DR2 may be uniform. The first openings PCO may be arranged to correspond to the inserting grooves PCG. In an embodiment, for example, the distance between the first openings PCO adjacent to each other in the second direction DR2 may not be uniform. The detailed features thereof will be described in detail with reference to FIG. 9D.

A plurality of second grooves MPL2 may be defined in the top surface of the through plate CPL. When viewed in the second direction DR2, the second grooves MPL2 may be defined between the first openings PCO adjacent to each other in the second direction DR2. The second grooves MPL2 may be arranged to correspond to the first grooves MPL1.

Referring to FIGS. 9A to 9B, elastic bodies SMD may be arranged in the second direction DR2. In an embodiment, for example, the distance between the elastic bodies SMD adjacent to each other in the second direction DR2 may be uniform.

In an embodiment, for example, the elastic body SMD may include a compression spring. In an embodiment, for example, the elastic modulus of the whole elastic bodies SMD may be in a range from about 500 gram-force (gf) to about 5000 gf. The elastic bodies SMD may have a substantially same elastic modulus as each other. However, the disclosure is not limited thereto. In an embodiment, the elastic modulus of at least one selected from the plurality of springs may be different from the elastic modulus of another spring of the plurality of springs.

The shape of the elastic bodies SMD may correspond to the shape of the grooves GR. In an embodiment, for example, the elastic bodies SMD may have a cylindrical shape to correspond to the shape of the grooves GR. However, the disclosure is not limited thereto. In another embodiment, as illustrated in FIG. 9C, elastic bodies SMDa may have the shape of a quadrangular column. In such an embodiment, the shape of the grooves GR may have the shape corresponding to a rectangle.

Referring back to FIGS. 9A and 9B, each of the fixing pins CPN may include a head part FSP and a body part PCY. In an embodiment, for example, each of the head part FSP may have a plane defined by the second direction DR2 and the third direction DR3.

Body parts PCY may extend in the first direction DR1 from the head parts FSP. The body parts PCY may have the shape corresponding to the springs of the elastic bodies SMD. In an embodiment, for example, the body portions PCY may have a cylindrical shape. However, this is provided as an example, and as illustrated in FIG. 9C, in an embodiment where the elastic body SMDa has the shape of a quadrangular column, the shape of the body parts PCY may be changed.

The fixing pins CPN may be arranged in the second direction DR2. In an embodiment, for example, the distance between the fixing pins CPN adjacent to each other in the second direction DR2 may be uniform. However, the disclosure is not limited thereto. In another embodiment, for example, the distance between the fixing pins CPN adjacent to each other in the second direction DR2 may be not uniform. The detailed features thereof will be described in detail with reference to FIG. 9D.

The fixing pins CPN may pass through the elastic bodies SMD and the connecting plate CTB. The elastic bodies SMD may be disposed to correspond to the first openings PCO defined or formed in the through plate CPL. The fixing pins CPN passing through the elastic bodies SMD and the through plate CPL may be coupled to the insertion grooves PCG.

Although not illustrated, a plurality of protruding parts may be disposed on an outer surface of the body parts PCY, and grooves may be defined inside the inserting grooves PCG to correspond to the protruding parts, such that the body parts PCY may be coupled to the inserting grooves PCG. However, the disclosure is not limited thereto. In an embodiment, for example, the body parts PCY and the inserting plate ESW may be welded to each other. The elastic body SMD, the connecting bar CTB, and the tensile bar ETB may be coupled to each other by the fixing pin CPN.

One side of opposite side of each of the elastic bodies SMD may make contact with the through plate CPL, and an opposite side of the each of the elastic bodies SMD may make contact with the head part FSP of the fixing pin CPN.

Referring to FIG. 9D, the fixing pins CPN may be arranged in the second direction DR2. The distance between the fixing pins CPN adjacent to each other in the second direction DR2 may be not uniform. The distance between the elastic bodies SMD coupled to the fixing pins CPN may not uniform. Although not illustrated, the distance between the first openings PCO (see FIG. 9B) defined or formed in the through plate CPL in the second direction DR2 may not be uniform. In addition, the distance between the inserting grooves PCG (see FIG. 9B) defined in the inserting plate ESW in the second direction DR2 may not be uniform.

The tensile bar ETB, the connecting bar CTB, the elastic bodies SMD, and the fixing pins CPN to be hereinafter described are substantially the same as those described above, and any repetitive detailed description thereof will be omitted.

Referring to FIG. 9E, the connecting part CPP may be coupled to the driving unit DU. The first arm AM1 and the second arm AM2 of the driving unit DU may be coupled to the tensile bar ETB of the connecting part CPP. The second pin protruding parts FPT2 (see FIG. 8A) of the first arm AM1 and the fourth pin protruding parts FPT4 (see FIG. 8A) of the second arm AM2 may be placed in the first guide grooves GDR1. The second fin protrusion parts FPT2 (see FIG. 8A) of the first arm AM1 and the fourth fin protrusion parts FPT4 (see FIG. 8A) of the second arm AM2 may move in the second direction DR2 along the first guide grooves GDR1.

Referring to FIGS. 9E and 9F, FIG. 9E is a view illustrating the driving unit DU and the connecting part CPP in the inserting mode, and FIG. 9F is a view the driving unit DU and the connecting part CPP in the spreading mode.

In an embodiment, as the first and second arms AM1 and AM2 are contracted in the first direction DR1, the tensile bar ETB and the connecting bar CTB may be moved to be close to the main plate MPL in the first direction DR1. When the first and second arms AM1 and AM2 are contracted or shrunk in the first direction DR1, a distance between the second pin protruding part FPT2 and the fourth pin protruding part FPT4 adjacent to each other in the second direction DR2 may be increased. When the first and second arms AM1 and AM2 are expanded or spread in the first direction DR1, the distance between the second pin protruding parts FPT2 and the fourth pin protruding parts FPT4 adjacent to each other in the second direction DR2 may be decreased.

When the driving unit DU is expanded, the distances between the main plate MPL and the second pin protruding parts FPT2 (see FIG. 8A) and the distance between the main plate MPL and the fourth pin protruding parts FPT4 (see FIG. 8A) may be increased.

When the first arm AM1 and the second arm AM2 are expanded in the first direction DR1, the connecting parts CPP coupled to the second and fourth pin protruding parts FPT2 and FPT4 may be moved in the first direction DR1 to be away from the main plate MPL.

FIG. 10A is a view illustrating the moving plate MVP. FIGS. 10B and 10C are views illustrating the coupling between the driving unit DU and the moving plate MVP.

FIGS. 10A to 10C are perspective views.

FIG. 10B is a view illustrating the moving plate in the inserting mode, and FIG. 10C is a view illustrating the moving plate in the spreading mode.

Since the driving unit DU and the connecting part CPP of FIGS. 10B and 10C are the same as the driving unit DU of FIG. 8A and the connecting part CPP of FIG. 9A, any repetitive detailed description of the driving unit DU and the connecting part CPP of FIGS. 10B and 10C will hereinafter be omitted or simplified.

Referring to FIGS. 3, 10A, and 10B, an embodiment of the extending module EMD of FIG. 3 may further include moving plates MVP. The moving plates MVP may be arranged in the first direction DR1. Hereinafter, one of two moving plates MVP will be mainly described. However, it will be understood that a remaining moving plate MVP of the two moving plates MVP may be substantially the same as the one moving plate MVP.

The moving plate MVP may include a stem part STP and branch parts BRP. The stem part STP may extend in the second direction DR2. Second guide grooves GDR2 may be defined in one side of sides, which are opposite to each other in the first direction DR1, of the stem part STP. The second guide grooves GDR2 may extend in the second direction DR2. The second guide grooves GDR2 may be arranged in the second direction DR2.

The branch parts BRP may extend in the first direction DR1 from the stem part STP. In an embodiment, for example, the branch parts BRP and the stem part STP may be integrally formed as a single unitary indivisible part. The branch parts BRP may be arranged in the second direction DR2. The distance between the branch parts BRP adjacent to each other in the second direction DR2 may be uniform.

The extending module EMD of FIG. 3 may include a plurality of rollers ROL. In an embodiment, for example, the rollers ROL may have a cylindrical shape. The rollers ROL may be interposed between the branch parts BRP adjacent to each other in the second direction DR2. The rollers ROL may be disposed to be adjacent to each other at one of sides, which are opposite to each other in the first direction DR1, of the branch parts BRP. The one side of the sides of the branch parts BRP may be placed away from the stem part STP in the first direction DR1. The rollers ROL may rotate about a rotation axis FX parallel to the second direction DR2.

Referring to FIG. 10B, the moving plate MVP may be coupled to the driving unit DU of FIG. 9E. The moving plate MVP may be disposed on the first arm AM1 and the second arm AM2. The first pin protruding part FPT1 of the first arm AM1 and the third pin protruding part FPT3 of the second arm AM2 may be placed in the second guide grooves GDR2 of the moving plate MVP. The first pin protruding parts FPT1 and the third pin protruding parts FPT3 may move in the second direction DR2 along the second guide grooves GDR2.

The moving plate MVP may be disposed on the connecting part CPP. The branch parts BRP of the moving plate MVP may be disposed in the first grooves MPL1 defined on the top surface of the inserting plate ESW and the second grooves MPL2 defined in the top surface of the through plate CPL. The first grooves MPL1 and the second grooves MPL2 may be disposed to have a shape corresponding to the branch parts BRP. Accordingly, the connecting part CPP may move in the first direction DR1 along the branch parts BRP.

Referring to FIGS. 10B and 10C, as the first and second arms AM1 and AM2 are contracted in the first direction DR1, the moving plates MVP may be moved to be close to the main plate MPL in the first direction DR1. When the first and second arms AM1 and AM2 are contacted in the first direction DR1, the distance between the first pin protruding parts FPT1 and the third pin protruding parts FPT3 adjacent to each other in the second direction DR2 may be increased.

As the first and second arms AM1 and AM2 are expanded in the first direction DR1, the moving plates MVP may move to be away from the main plate MPL in the first direction DR1. The variation in distance from the main plate MPL to the first and third protruding parts FPT1 and FPT3 in the first direction DR1 may be equal to the moving distance of the moving plate MVP linked to the first and third pin protruding parts FPT1 and FPT3. When the first and second arms AM1 and AM2 are expanded in the first direction DR1, the distance between the first pin protruding parts FPT1 and the third pin protruding parts FPT3 adjacent to each other in the second direction DR2 may be decreased.

FIG. 11A is a perspective view illustrating the coupling between the support bars SSB and the extending module EMD. FIG. 11B is a cross-sectional view taken along line II-II′ illustrated in FIG. 11A. FIG. 12A is a perspective view illustrating the spreading mode of the extending module EMD illustrated in FIG. 11A. FIG. 12B is a cross-sectional view taken along line III-III′ illustrated in FIG. 12A. FIG. 12C is a view illustrating the moving distance between the moving plate MVP and the tensile bar ETB.

Particularly, FIGS. 11A and 11B are views illustrating the extending module EMD in the inserting mode, and FIGS. 12A and 12B are views illustrating the extending module EMD in the spreading mode.

FIGS. 11A and 12A illustrate only the support bars SSB of the display assembly PCR of FIGS. 11B and 12B for the convenience of illustration.

Hereinafter, any repetitive detailed description of components, which are the same as components described with reference to drawings described above, of components illustrated in FIGS. 11A to 12C will be omitted or simplified.

Hereinafter, since the connecting bar CTB, the tensile bar ETB, and the support bars SSB disposed on the left side of the fixed plate SPL may be substantially the same as the support bars SSB, the connecting bar CTB, and the tensile bar ETB disposed on the right side of the fixed plate SPL, so the following description will be made while focusing on the support bars SSB, the connecting bar CTB, and the tensile bar ETB disposed at the left side of the fixed plate SPL.

Referring to FIGS. 11A and 11B, the second regions A2 of the display assembly PCR in the inserting mode may be bent. A portion of the second regions A2 may be disposed under the first region A1. The extending module EMD may be interposed between the first region A1 and the second regions A2. The display assembly PCR may be coupled to the extending module EMD. The second regions A2 of the display assembly PCR may be coupled to the connecting bar CTB of the extending module EMD.

Some support bars SSB among the support bars SSB may be disposed under the moving plate MVP. The some support bars SSB disposed under the moving plate MVP may be arranged in the first direction DR1. Other support bars among the support bars SSB may be arranged in a curved shape along the outer surface of the roller ROL. Remaining support bars SSB among the support bars SSB may be disposed at an upper portion of the moving plate MVP.

The support bars SSB may be coupled to the extending module EMD. In an embodiment, the coupling support bar COB may be coupled to the connecting bar CTB. The coupling support bar COB may be coupled to the bottom surface of the connecting plate CSW. The remaining support bars SSB may be connected to the connecting bar CTB by the coupling support bar COB.

The fixing pin CPN passing through the elastic body SMD and the through plate CPL may compress the elastic body SMD and may be coupled to the inserting plate ESW. In this case, elastic force is generated from the elastic body SMD to restore the elastic body SMD from a compressed state to a normal state. In this case, the normal state refers to a state in which the elastic force is not generated from the elastic body SMD. Hereinafter, the state in which the elastic body SMD is compressed to generate the elastic force may be defined as a first state, and the state in which the elastic force is more relaxed than the first state may be defined as a second state.

The elastic force of the elastic body SMD is applied to the coupling support bar COB coupled to the through plate CPL. Accordingly, tensile force may be generated from the display assembly PCR. The tensile force acts in a direction opposite to a direction of the elastic force. When viewed based on the connecting bar CTB at the left side as illustrated in FIG. 11B, the tensile force is generated in the direction opposite to the first direction DR1 facing the tensile bar ETB from the coupling support bar COB. The tensile force and the elastic force may be equivalent to each other.

The shortest distance from the fixed plate SPL to the rotation axis FX of the roller ROL may be defined as a first first length (hereinafter, will be referred to as “(1-1)-th length”) L1-1 in the inserting mode. The shortest distance from the fixed plate SPL to the coupling support bar COB may be defined as a first second length (hereinafter, will be referred to as “(2-1)-th length”) L2-1. The longest distance from the fixed plate SPL to the inserting plate ESW may be defined as a first third length (hereinafter, will be referred to as “(3-1)-th length”) L3-1. The distance between the tensile bar ETB and the connecting bar CTB may be defined as a first distance D1.

Referring to FIGS. 12A to 12C, as the first arm AM1 and the second arm AM2 are expanded in the first direction DR1, the first pin protruding part FPT1 of the first arm AM1 and the third pin protruding part FPT3 of the second arm AM2 may be moved in the first direction DR1 along the second guide grooves GDR2. The distance between the first pin protruding parts FPT1 and the third pin protruding parts FPT3 adjacent to each other in the second direction DR2 may be decreased. Accordingly, the moving plate MVP may be moved to be away from the main plate MPL in the first direction DR1.

As the main plate MPL is moved, a portion of the second regions A2 may be moved from a lower portion of the moving plate MVP to an upper portion of the main plate MPL. A portion of the second regions A2 may provide the same plane as that of the first region A1.

When the moving plate MVP moves in the first direction DR1, the rollers ROL coupled to the moving plate MVP may move in the same direction as the moving plate MVP. The roller ROL may rotate about the rotation axis FX. In an embodiment, for example, the roller ROL may be rotated clockwise.

When the roller ROL rotates, the support bars SSB disposed under the moving plate MVP and the support bars SSB disposed on the outer surface of the roller ROL may be moved to the upper portion of the moving plate MVP along the outer surface of the roller ROL. In the spreading mode, the number of support bars SSB disposed on the moving plate MVP may be increased. As illustrated in FIG. 2B, the area of the display region DA exposed to the outside from the case CS (see FIG. 2B) may be increased.

The ratio of the moving distance of the support bars SSB to the moving distance of the moving plate MWP may be varied. In an embodiment, for example, the ratio of the moving distance of the support bars SSB to the moving distance of the moving plate MWP may be about 1:2.

The shortest distance from the fixed plate SPL to the rotation axis FX of the roller ROL may be defined as a second first length (hereinafter, will be referred to as “(1-2)-th length”) L1-2 in the spreading mode. The shortest distance from the fixed plate SPL to the coupling support bar COB may be defined as a second second length (hereinafter, will be referred to as “(2-2)-th length”) L2-2 in the spreading mode.

A value obtained by subtracting the (1-1)-th length L1-1 from the (1-2)-th length L1-2 may be defined as a moving distance of the roller ROL. A value obtained by subtracting the (2-1)-th length L2-1 from the (2-2)-th length L2-2 may be defined as a moving distance of the coupling support bar COB.

A value obtained by subtracting the (1-1)-th length L1-1 from the (1-2)-th length L1-2 may be smaller than a value obtained by subtracting the (2-1)-th length L2-1 from the (2-2)-th length L2-2. A value obtained by subtracting the (2-1)-th length L2-1 from the (2-2)-th length L2-2 may be smaller than a value obtained by subtracting the (1-1)-th length L1-1 from the (1-2)-th length L1-2. Accordingly, a ratio of the moving distance of the connecting bar CTB connected to the coupling support bar COB to the moving distance of the moving plate MVP in the first direction DR1 may be about 1:2.

Referring to FIGS. 11B, 12B, and 12C, when the first arm AM1 and the second arm AM2 are expanded, the tensile bars ETB coupled to the second and fourth pin protruding parts FPT2 and FPT4 (see FIG. 8A) of the first arm AM1 and the second arm AM2 may be moved in the first direction DR1.

The moving distance of the connecting bar CTB to the moving distance of the moving plate MVP described above may be substantially the same as the moving distance of the tensile bar ETB to the moving distance of the moving plate MVP. For the convenience of illustration, in FIG. 12C, the first arm AM1 and the second arm AM2 are shown in the form of a straight line in brief, and the first to fourth pin protruding parts FPT1 to FPT4 and the first and second pins PU1 and PU2 are shown in the form of a dot in brief.

As illustrated in FIG. 12C, the ratio of the moving distance of the second and fourth pin protruding parts FPT2 and FPT4 to the moving distances of the first and third pin protruding parts FPT1 and FPT3 may be about 1:2. The moving distance of the tensile bars ETB connected to the second and fourth pin protruding parts FPT2 and FPT4 in the first direction DR1 may be greater than the moving distance of the moving plate MVP connected to the first and third pin protruding parts FPT1 and FPT3 in the first direction DR1. The ratio between the moving distance of the tensile bars ETB in the first direction DR1 and the moving distance of the moving plate MVP in the first direction DR1 may be about 1:2. The moving distance of the tensile bars ETB in the first direction DR1 and the moving distance of the connecting bars CTB in the first direction DR1 may be equal to each other.

The longest distance from the fixed plate SPL to the inserting plate ESW may be defined as a second third length (hereinafter, will be referred to as “(3-2)-th length”) L3-2 in the spreading mode. A value obtained by subtracting the (3-1)-th length L3-1 from the (3-2)-th length L3-2 may be equal to a value obtained by subtracting the (2-1)-th length L2-1 from the (2-2)-th length L2-2. Accordingly, in the spreading mode, the tensile bar ETB and the connecting bar CTB may be maintained to be spaced apart from each other. The distance between the tensile bar ETB and the connecting bar CTB may be defined as a second distance D2, in the spreading mode. The first distance D1 and the second distance D2 may be substantially equal to each other. As the distance between the tensile bars ETB and the connecting bars CTB is maintained, the elastic body SMD may be maintained in the compressed state.

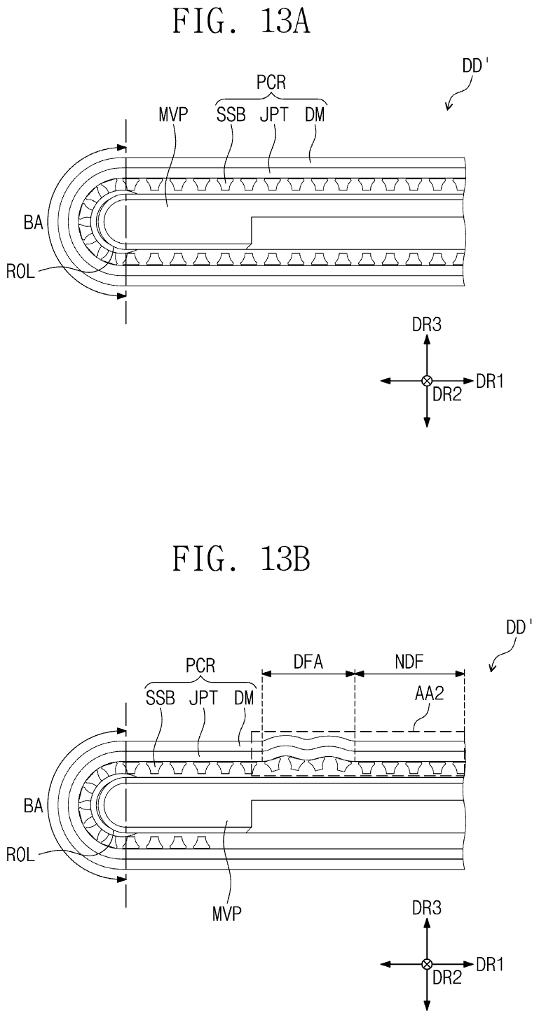

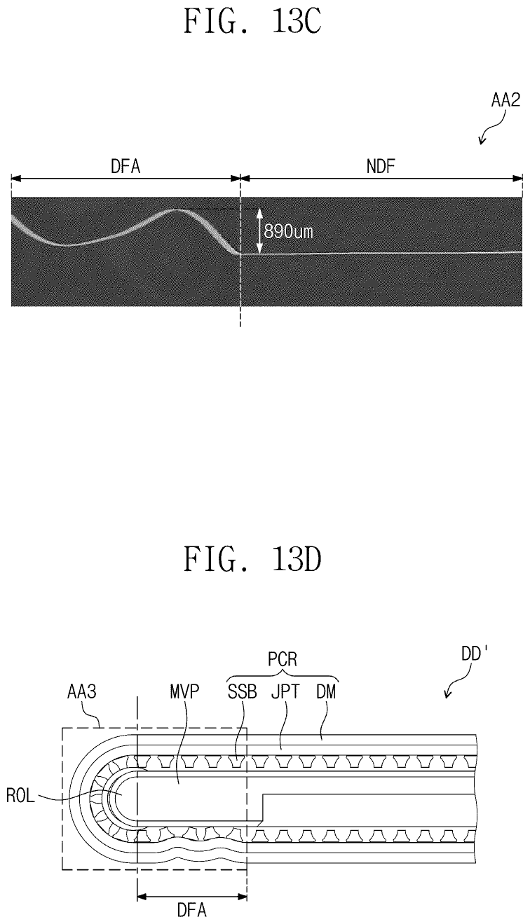

FIGS. 13A to 13E are views illustrating a display device DD′ according to a comparative embodiment.

FIG. 13A is a cross-sectional view illustrating the display device DD′ before a furrow is formed in the inserting mode, and FIG. 13B is a cross-sectional view illustrating the display device DD′ having the furrow in the spreading mode. FIG. 13C is a view illustrating a result obtained by measuring a second region AA2 illustrated in FIG. 13B through an observation device. FIG. 13D is a cross-sectional view illustrating a state in which a defect is caused in the display device DD′ in the inserting mode. FIG. 13E is an image obtained by photographing a part deformed in the third region AA3 illustrated in FIG. 13D.

Hereinafter, any repetitive detailed description of components, which are the same as components described with reference to drawings described above, of components illustrated in FIGS. 13A to 13E will be omitted or simplified.

Referring to FIGS. 13A to 13E, as illustrated in FIG. 13A, the display device DD′ may include a bent section BA provided around the roller ROL. In the bent section BA, a stress may be applied to the coupling part JPT and the display module DM disposed on the outer surface of the roller ROL. When the extending module EMD (refer to FIG. 3) is repeatedly changed from the spreading mode to the inserting mode, or from the inserting mode to the spreading mode, stress may be repeatedly applied to the coupling part JPT and the display module DM disposed on the outer surface of the roller ROL.

Accordingly, the fatigue failure may be caused to the coupling part JPT and the display module DM of the display assembly PCR disposed on the outer surface of the roller ROL. The fatigue failure may refer to that a material is plastically deformed when a stress lower than the breaking stress is repeatedly applied to the material. The plastic deformation refers to that the material is permanently deformed without being restored to an original shape even if external force is removed from the material.

If the fatigue failure is caused, the coupling part JPT and the display module DM disposed on the outer surface of the roller ROL may be plastically deformed. The length of the coupling part JPT and the length of the display module DM may be increased.

As illustrated in FIG. 13B, in the spreading mode, a deformed part DFA of the display module DM and the coupling part JPT may be moved to an upper portion of the moving plate MVP.

A part (the deformed part DFA) in which the length of the display module DM and the coupling part JPT is increased may make a furrow on the front surface of the display device DD′. As illustrated in FIG. 13C, the furrow having the shape of ‘M’ may be caused in the deformed part DFA of the display module DM and the coupling part JPT. The deformed part DFA of the display module DM may protrude upward from a peripheral part NDF. For example, as illustrated in FIG. 13C, the height of the deformed part DFA may be about 890 micrometers (μm) higher than the height of the peripheral part NDF.

The furrow made by the display module DM and the coupling part JPT may be exposed to the outside from the case CS of FIG. 3. When the furrow made by the display module DM and the coupling part JPT is exposed to the outside, the furrow made by the display module DM and the coupling part JPT may be viewed by the user, such the surface quality of the display device DD′ may be reduced.

As illustrated in FIG. 13B, the deformed part DFA of the display module DM and the coupling part JPT may be moved to a lower portion of the moving plate MVP in the inserting mode. A part of the coupling part JPT and a part of the display module DM under the moving plate MVP may have the furrow. Accordingly, when the display device DD′ becomes in the inserting mode, the deformed part of the support bars SSB, the deformed part of the coupling part JPT, and the deformed part of the display module DM interfere with the extending module EMD (see FIG. 3) or the case CS (see FIG. 3) to cause a failure to the display device DD′.

The furrow made by the coupling part JPT and the display module DM may be formed in various aspects. The furrow may be made in all the coupling part JPT and the display module DM, may be made in any one of the coupling part JPT and the display module DM, or may be made at an upper portion and a lower portion of the moving plate MVP. As illustrated in the image of FIG. 13E, the furrow may be made in the coupling part JPT throughout the wide region. Accordingly, buckling may be caused to the support bars SSB attached to the coupling part JPT.

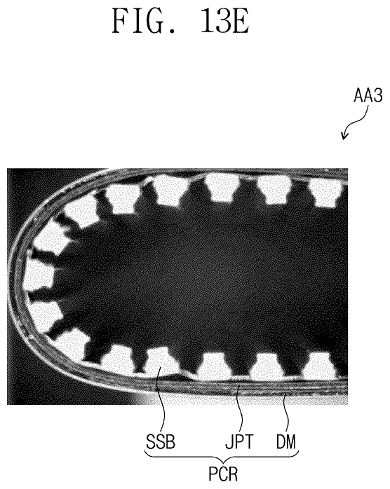

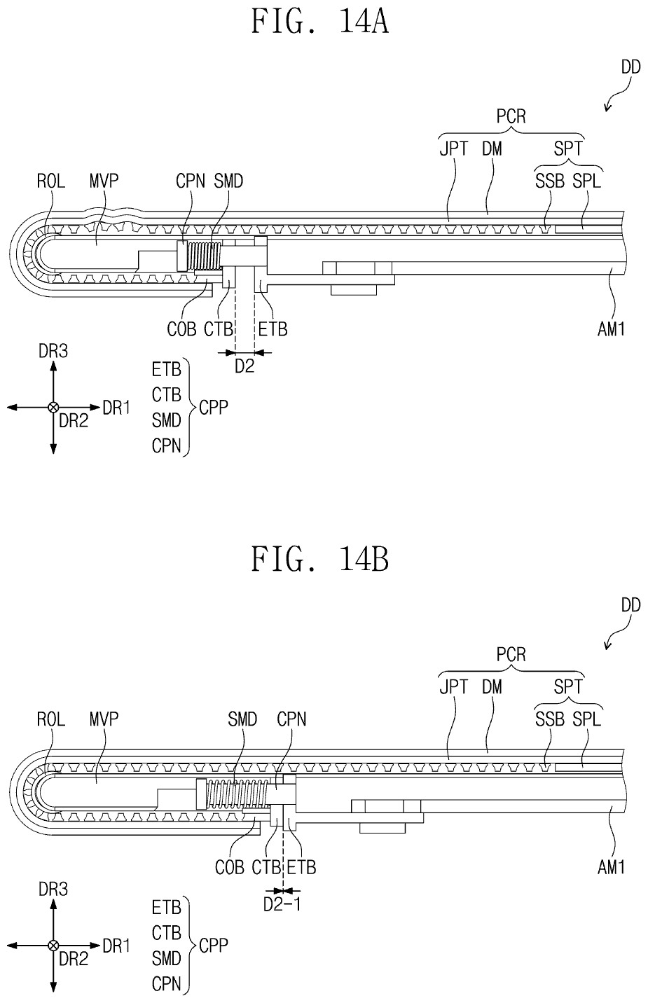

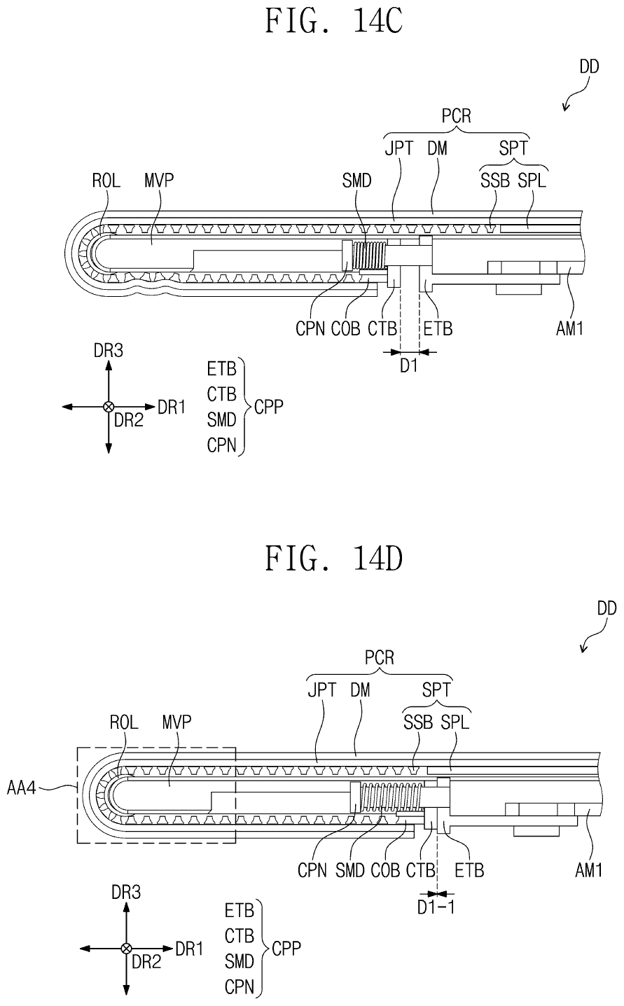

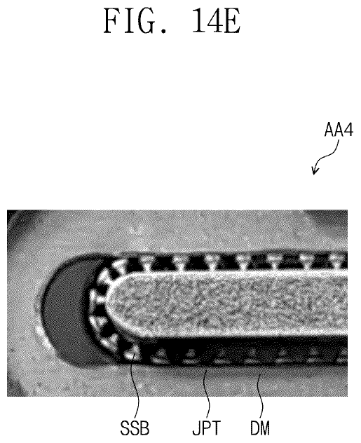

FIGS. 14A to 14E are views illustrating a mechanism for resolving the issue of the furrow according to an embodiment of the disclosure.

FIGS. 14A and 14B are cross-sectional views illustrating the display device DD in the spreading mode, and FIGS. 14C and 14D are cross-sectional views illustrating the display device DD in the inserting mode.

FIG. 14E illustrates a photograph obtained by capturing a part corresponding to a fourth region AA4 illustrated in FIG. 14D.

Hereinafter, any repetitive detailed description of components, which are the same as components described with reference to drawings described above, of components illustrated in FIGS. 14A to 14E will be omitted or simplified.

In an embodiment, as described with reference to FIG. 13A, as the display device DD′ repeatedly operates between the inserting mode and the spreading mode, the furrow may be made at a portion of the display assembly PCR as illustrated in FIG. 14A.

In an embodiment, as described with reference to FIGS. 11B and 12B, the connecting part CPP is provided in a way such that elastic force generated from the elastic body SMD in the first state is equivalent to tensile force generated from the display assembly PCR. As illustrated in FIG. 14A, when a furrow is made in a portion of the display assembly PCR, the equivalence between the elastic force and the tensile force is broken.

The elastic body SMD in the first state is changed to be the third state, as illustrated in FIG. 14B. As the elastic force is reduced, the length of the elastic body SMD is increased, and the connecting bar CTB may move toward the tensile bar ETB. The distance between the connecting bar CTB and the tensile bar ETB may be reduced to the (2-1)-th distance D2-1. As the elastic force is reduced, the tensile force is decreased from the display assembly PCR. The reduced elastic force and the reduced tensile force may be equivalent to each other. According to an embodiment of the disclosure, the connecting bar CTB and the tensile bar ETB may make contact with each other. In this case, the (2-1)-th distance D2-1 may be substantially zero (0).

When the connecting bar CTB moves in the first direction DR1 toward the tensile bar ETB, the coupling support bar COB connected to the connecting bar CTB, the coupling part JPT connected to the coupling support bar COB, and the display module DM connected to the coupling part JPT may move in the first direction DR1. Accordingly, the furrow made in the coupling part JPT and the display module DM may be spread to be flat. As illustrated in FIG. 14E, the buckling may be removed or reduced from the support bars SSB attached to the coupling part JPT having the furrow. Accordingly, the surface quality of the display device DD may be improved.

The principle for removing the furrow in the spreading mode has been described with reference to FIGS. 14A and 14B, and may be identically applied to the description to be made with reference to FIGS. 14C and 14D.

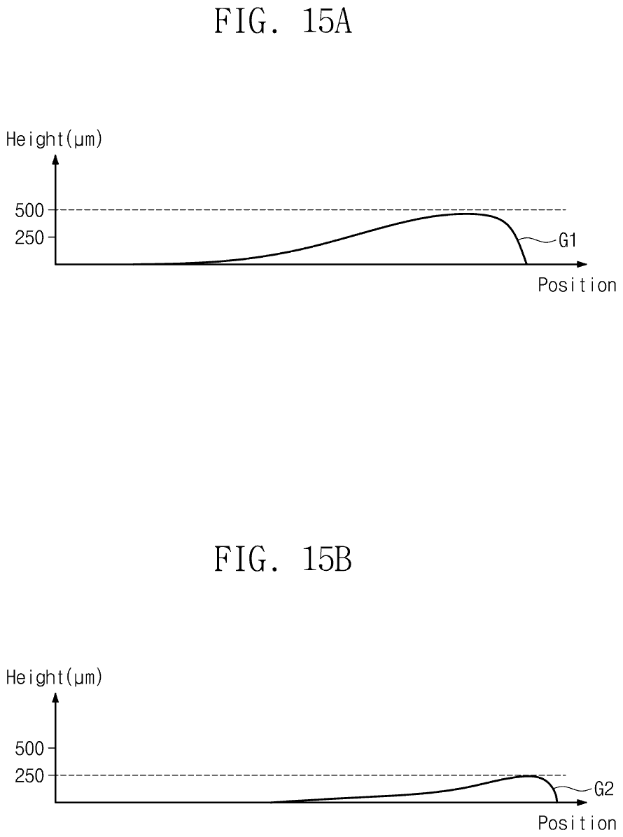

FIGS. 15A and 15B are views illustrating the height of the furrow of the display module DM depending on the elastic modulus of the elastic body illustrated in FIG. 14A.

Particularly, FIGS. 15A and 15B are graphs illustrating the measurement of deformation amount of the front surface DA (see FIG. 2B) of the display module DM spread by the elastic body SMD of FIGS. 14A and 14B, by an observation device.

Referring to FIGS. 13C, 14B, 15A, and 15B, an x-axis of the graphs of FIGS. 15A and 15B may be defined as a position of the display module DM disposed on the moving plate MVP, and a y-axis of the graphs of FIGS. 15A and 15B may be defined as the deformation amount of the display module DM.

A first graph G1 shown in FIG. 15A is a measurement result of the front surface DA (see FIG. 2B) of the display module DM spread by the elastic body SMD having an elastic modulus of about 500 gf. A second graph G2 shown in FIG. 15B is a measurement result of the front surface DA (see FIG. 2B) of the display module DM spread by the elastic body SMD having an elastic modulus of about 1800 gf.

As illustrated in FIG. 13C, when the deformation amount of the display module DM is about 890 μm, the elastic body SMD may be uncompressed. As the elastic body SMD is uncompressed, the deformation amount of the display module DM may be reduced.

As the elastic modulus of the elastic body SMD is increased, the elastic force of the elastic body SMD may be increased. In detail, in the graph of FIG. 15A, when the elastic modulus of the elastic body SMD is about 500 gf, the deformation amount of the display module DM may be decreased to about 500 μm. In the graph of FIG. 15B, when the elastic modulus of the elastic body SMD is about 1800 gf, the deformation amount of the display module DM may be decreased to about 250 μm.

As the elastic modulus of the elastic body SMD is increased, the deformation amount of the display module DM may be decreased, such the surface quality of the display device DD (see FIG. 1) may be improved.

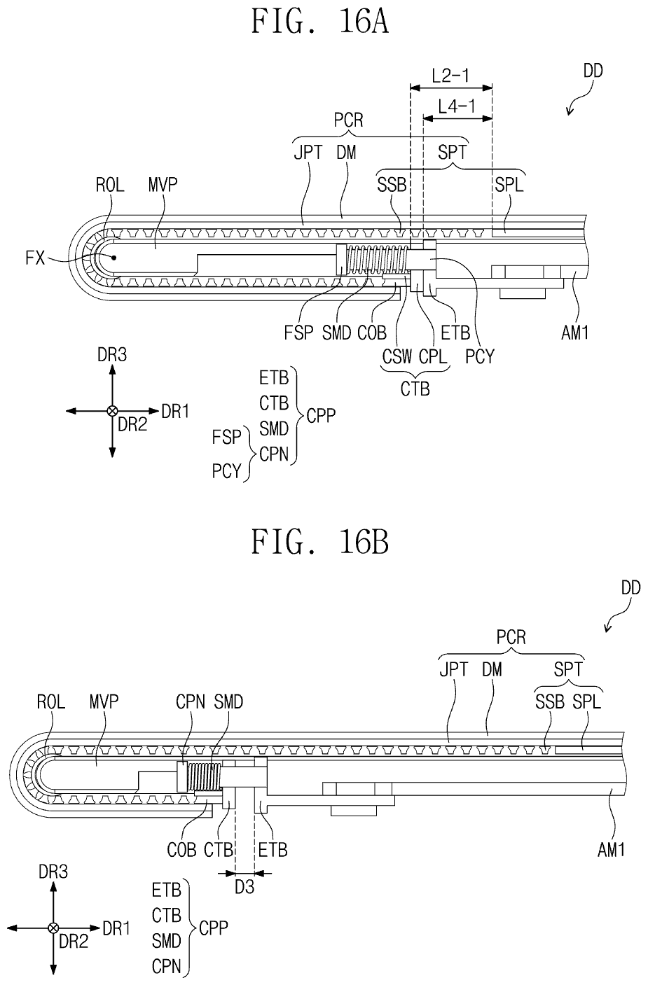

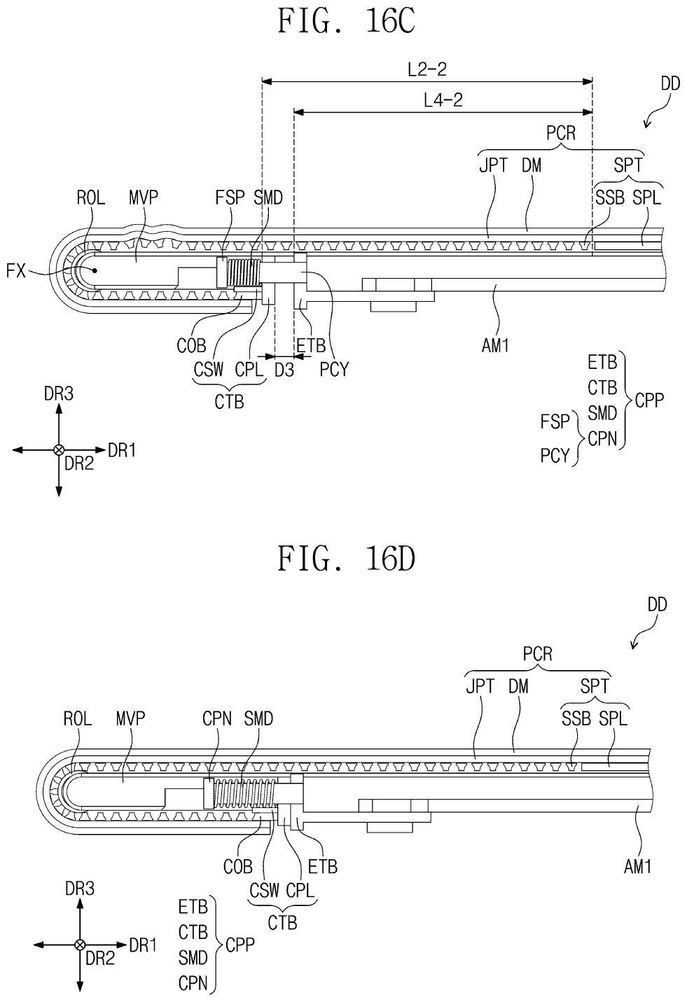

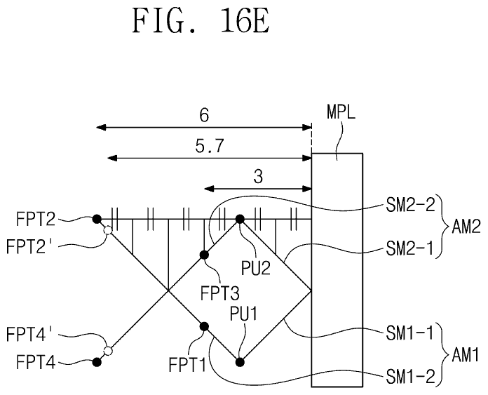

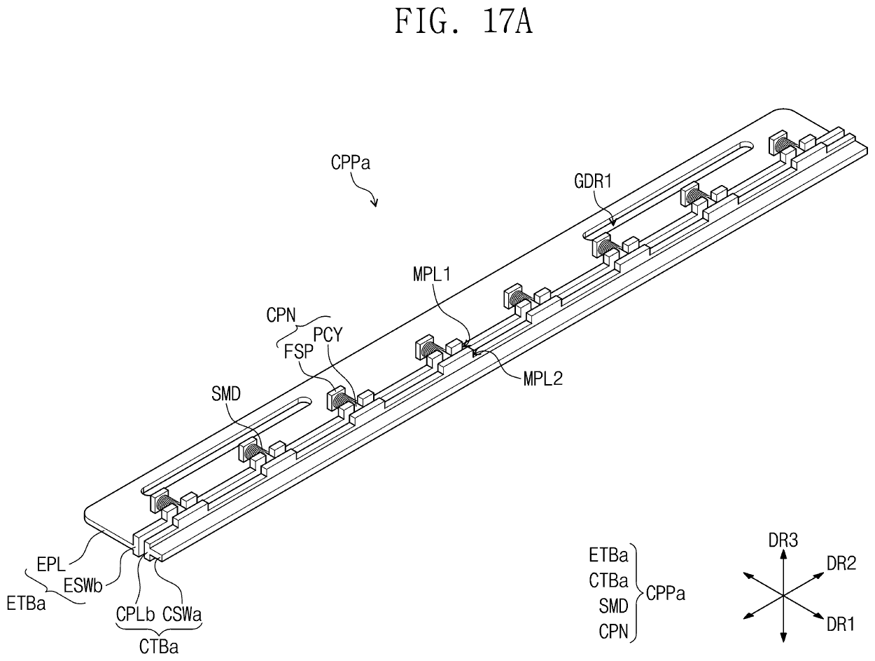

FIGS. 16A to 16E are cross-sectional views of the display device DD according to an embodiment of the disclosure.

Particularly, FIG. 16A is a cross-sectional view illustrating the display device DD in the inserting mode, and FIGS. 16B, 16D, and 16E are cross-sectional views of the display device DD in the spreading mode.

Hereinafter, any repetitive detailed description of components, which are the same as components described with reference to drawings described above, of components illustrated in FIGS. 16A to 16E will be omitted or simplified.

Referring to FIG. 16A, when the display device DD is in the inserting mode, the connecting bar CTB and the tensile bar ETB may make contact with each other. The elastic body SMD interposed between the head part FSP and the through plate CPL may be in the third state.

When the elastic body SMD is in the third state, elastic force applied to the connecting bar CTB may be reduced by the elastic body SMD, or may not be applied to the connecting bar CTB. The elastic force may not act on the coupling support bar COB connected to the connecting bar CTB, the coupling part JPT connected to the coupling support bar COB, and the display module DM connected to the coupling part JPT. Accordingly, the display module DM may be effectively prevented from being damaged due to elastic force.

The shortest distance from the fixed plate SPL to the coupling support bar COB may be defined as the (2-1)-th length L2-1 in the inserting mode of the display device DD. The longest distance from the fixed plate SPL to the tensile bar ETB may be defined as a first fourth length (hereinafter, will be referred to as “(4-1)-th length”) L4-1.

Referring to FIGS. 16A, 16B, and 16C, when the display device DD is changed to be in the inserting mode from the spreading mode, the moving distance of the coupling support bar COB, and the moving distance of the connecting bar CTB may be greater than the moving distance of the moving plate MVP.

In an embodiment, for example, the ratio of the moving distance of the coupling support bar CBO to the moving distance of the moving plate MWP may be about 1:2. The ratio between the moving distance of the moving plate MVP and the moving distance of the connecting bar CTB connected to the coupling support bar COB may be about 1:2. The moving distance of the coupling support bar COB and the moving distance of the connecting bar CTB to the moving distance of the moving plate are substantially the same as those described above with reference to FIGS. 12A to 12C, and any repetitive detailed description thereof will be omitted.

As illustrated in FIG. 16C, when the display device DD is in the spreading state, a distance from the first and third pin protruding parts FPT1 and FPT3 to one side of the main plate MPL may be different from a distance from the second and fourth pin protruding parts FPT2′ and FPT4′ to one side of the main plate MPL. The distance from the second and fourth pin protruding parts FPT2′ and FPT4′ to one side of the main plate MPL to the distance from the first and third pin protruding parts FPT1 and FPT3 to the one side of the main plate MPL may make the ratio of about 1:1.9. The moving distance of the moving plate MVP connected to the first and third pin protruding parts FPT1 and FPT3 and the moving distance of the tensile bar ETB connected to the second and fourth pin protruding parts FPT2′ and FPT4′ may make the ratio of 1:1.9.

The moving distance of the connecting bars CTB and the moving distance of the tensile bar ETB may be different from each other. The moving distance of the connecting bar CTB may be greater than the moving distance of the tensile bar ETB. In an embodiment, for example, the moving distance of the tensile bar ETB to the moving distance of the connecting bars CTB may make the ratio of about 2:1.9.

The shortest distance from the fixed plate SPL to the coupling support bar COB may be defined as the (2-2)-th length L2-2 in the spreading mode of the display device DD. The longest distance from the fixed plate SPL to the tensile bar ETB may be defined as a second fourth length (hereinafter, will be referred to as “(4-2)-th length”) L4-2.

A value obtained by subtracting the (2-1)-th length L2-1 from the (2-2)-th length L2-2 may be greater than a value obtained by subtracting the (4-1)-th length L4-1 from the (4-2)-th length L4-2. The value obtained by subtracting the (4-1)-th length L4-1 from the (4-2)-th length L4-2 to the value obtained by subtracting the (2-1)-th length L2-1 from the (2-2)-th length L2-2 may be 2:1.9.

As the moving distance of the connecting bar CTB is greater than the moving distance of the tensile bar ETB, the connecting bars CTB and the tensile bar ETB may be spaced apart from each other in the first direction DR1. The distance between the connecting bar CTB and the tensile bar ETB may be defined as the third distance D3, in the spreading state of the display device DD.

As the connecting bar CTB and the tensile bar ETB are spaced apart from each other, the state of the elastic body SMD interposed between the head part FSP and the through plate CPL may be changed from the third state to the first state. The variation in length of the elastic body SMD may be equal to a value obtained by subtracting the moving distance of the tensile bar ETB from the moving distance of the connecting bars CTB. The variation in length of the elastic body SMD may be equal to the third distance D3.

Referring to FIGS. 16D and 16E, in the spreading state, when the furrow is formed in the coupling part JPT and the display module DM, the elastic body SMD in the first state is uncompressed to be the third state. The principle for removing the furrow in the spreading mode has been described with reference to FIGS. 14A and 14B, and may be identically applied to the description to be made with reference to FIGS. 14C and 14D.

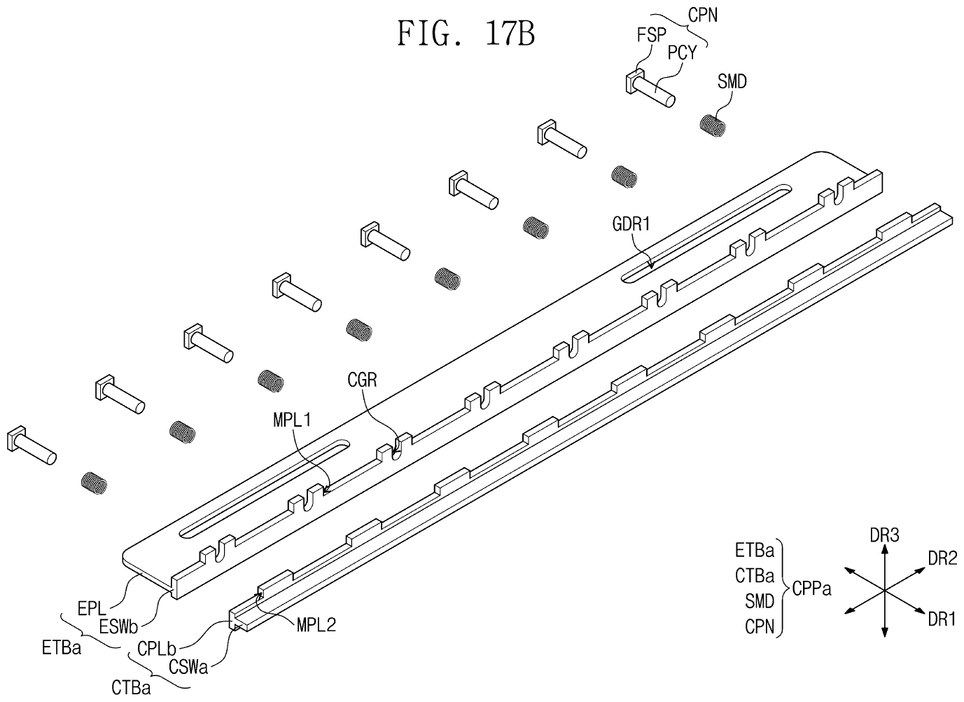

FIGS. 17A and 17B are views illustrating a connecting part according to an embodiment.

FIG. 17A illustrates a perspective view of the connecting part CPPa, and FIG. 17B is an exploded perspective view of the connecting part CPPa illustrating in FIG. 17A.

Hereinafter, any repetitive detailed description of components, which are the same as components described with reference to drawings described above, of components illustrated in FIGS. 17A to 17B will be omitted or simplified.

Referring to FIGS. 17A and 17B, an embodiment of the connecting part CPPa may include a tensile bar ETBa, a connecting bar CTBa, the elastic bodies SMD, and the fixing pins CPN. The tensile bar ETBa may extend in the second direction DR2. In an embodiment, for example, when viewed in the second direction DR2, the side surface of the tensile bar ETBa may have the shape obtained by rotating ‘T’ at 90 degrees.

The tensile bar ETBa may include the coupling plate EPL and an inserting plate ESWb. The coupling plate EPL may be parallel to a plane defined by the first direction DR1 and the second direction DR2, and may extend to be longer in the second direction DR2 rather than the first direction DR1.

A plurality of first guide grooves GDR1 may be defined or formed in a coupling plate EPL. The first guide grooves GDR1 may be formed at one side of sides, which are opposite to each other in the first direction DR1, of the coupling plate EPL to be adjacent to each other. The opposite side of the sides, which are opposite to each other in the first direction DR1, of the coupling plate EPL may be defined as a side facing the connecting bar CTBa.

Each of the first guide grooves GDR1 may extend in the second direction DR2. The first guide grooves GDR1 may be arranged in the second direction DR2. In an embodiment, for example, although two first guide grooves GDR1 are illustrated, the number of first guide grooves GDR1 is not limited thereto.

The inserting plate ESWb may be disposed at an opposite side of the sides, which are opposite to each other in the first direction DR1, of the coupling plate EPL. In an embodiment, for example, the coupling plate EPL and the inserting plate ESWb may be integrally formed as a single unitary indivisible part.

The inserting plate ESWb may extend in the second direction DR2. The length of the inserting plate ESWb in the third direction DR3 may be longer than the length of the coupling plate EPL in the third direction DR3. When viewed in the second direction DR2, a top surface and a bottom surface, which are opposite to each other in the third direction DR3, of the inserting plate ESWb may protrude from a top surface and a bottom surface of the coupling plate EPL, respectively.

A plurality of first grooves MPL1 and a plurality of second openings CGR may be defined or formed in the top surface of the inserting plate ESWb. When viewed in the first direction DR1, the first grooves MPL1 may be arranged in the second direction DR2. The second openings CGR may be arranged in the second direction DR2. The first grooves MPL1 and the second openings CGR may be alternately arranged in the second direction DR2. The second openings CGR may be defined between the first grooves MPL1 adjacent to each other in the second direction DR2.

The first grooves MPL1 may extend downward from the top surface of the inserting plate ESWb. In an embodiment, for example, the first grooves MPL1 may have the shape corresponding to a rectangle.

The second openings CGR may extend downward from the top surface of the inserting plate ESWb. The bottom surface of the inserting plate ESWb defining the second openings CGR may have a concave shape.

In an embodiment, for example, the distance between the second openings CGR adjacent to each other in the second direction DR2 may be uniform. The disclosure is not limited thereto. In an embodiment, for example, the distance between the second openings CGR adjacent to each other in the second direction DR2 may not be uniform.

The connecting bars CTBa and the tensile bar ETBa may be arranged in the first direction DR1. The connecting bar CTBa may be disposed to be adjacent to one side of sides, which are opposite to each other in the first direction DR1, of the inserting plate ESWb. The connecting bar CTBa may extend in the second direction DR2. In an embodiment, for example, when viewed in the second direction DR2, the connecting bar CTBa may have the shape obtained by rotating ‘T’ at 90 degrees. The opposite side of the sides, which are opposite to each other in the first direction DR1, of the inserting plate ESWb may be defined as a side facing the coupling plate EPL.

The connecting bars CTBa may include the connecting plate CSWa and a through plate CPLb. The coupling plate CSWa may be parallel to a plane defined by the first direction DR1 and the second direction DR2, and may extend to be longer in the second direction DR2 rather than the first direction DR1.

The through plate CPLb may be disposed at one side of the sides, which are opposite to each other in the first direction DR1, of the connecting plate CSWa. In an embodiment, for example, the connecting plate CSWa and the through plate CPLb may be integrally formed as a single unitary indivisible part. The one side of the sides, which are opposite to each other in the first direction DR1, of the connecting plate CSWa may be defined as a side facing the tensile bar ETBa.

A plurality of second grooves MPL2 may be defined in the top surface of the through plate CPLb. The second grooves MPL2 may extend in the third direction DR3 from the top surface of the through plate CPLb. The second grooves MPL2 may have the shape corresponding to a rectangle.

The second grooves MPL2 may be arranged in the second direction DR2. The second grooves MPL2 may be arranged to correspond to the first grooves MPL1. Although not illustrated, when the moving plate MVP (see FIG. 11A) is coupled to the connecting part CPPa, the branch parts BRP of the moving plate MVP (see FIG. 11A) may be disposed in the first grooves MPL1 and the second grooves MPL2.

The elastic bodies SMD may be disposed to be adjacent to one side of the coupling plate EPL. The elastic bodies SMD may be arranged in the second direction DR2. In an embodiment, for example, the distance between the elastic bodies SMD adjacent to each other in the second direction DR2 may be uniform.

The fixing pins CPN may pass through the elastic bodies SMD and the tensile bar ETBa. The fixing pins CPN may be coupled to the connecting bars CTBa through the second openings CGR. The fixing pins CPN may compress the elastic bodies SMD and may be coupled to the connecting bar CTBa.

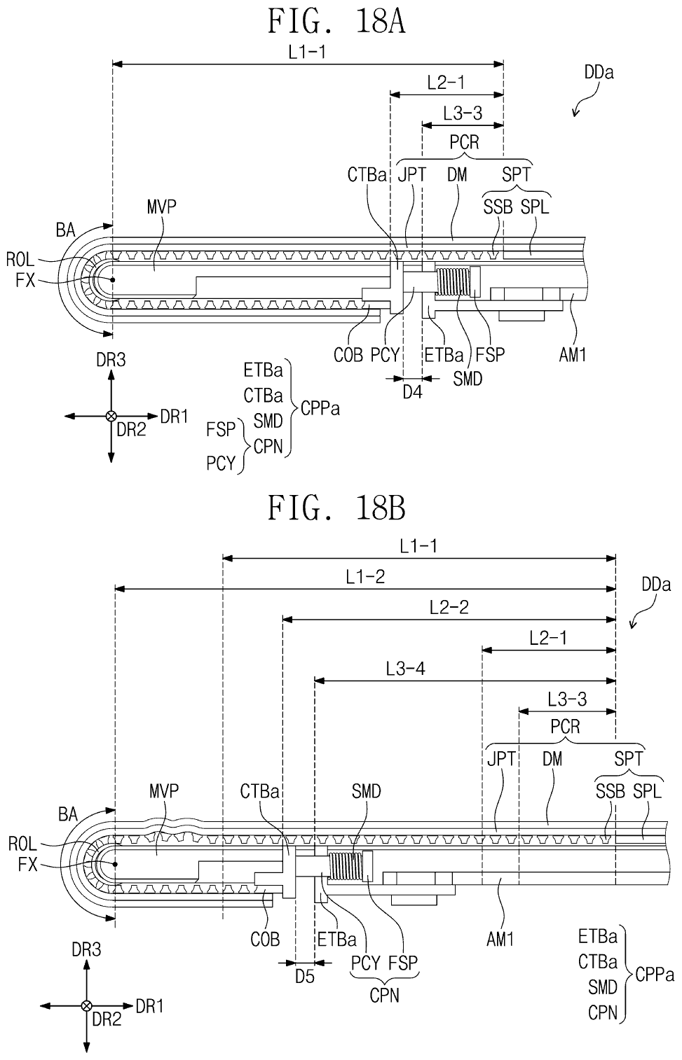

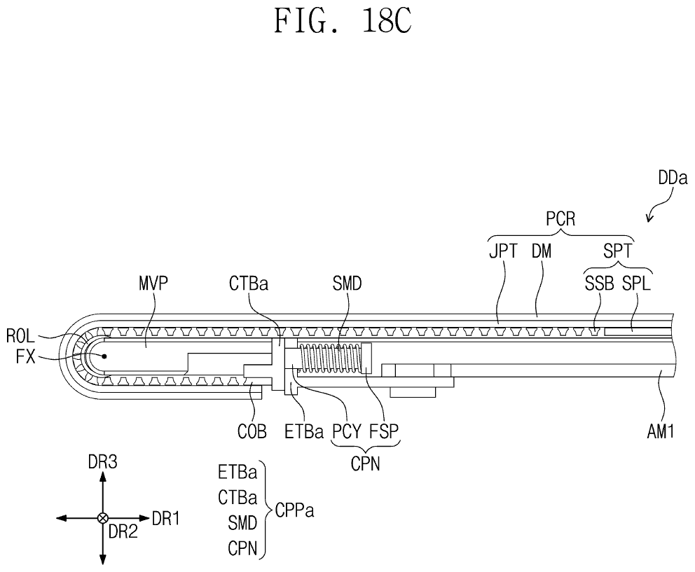

FIGS. 18A to 18C are views illustrating the operation of the connecting part illustrated in FIG. 17A.

Particularly, FIG. 18A is a cross-sectional view illustrating the structure of the connecting part in the inserting mode, and FIG. 18B and FIG. 18C are cross-sectional views illustrating the structure of the connecting part in the spreading mode.

Although FIGS. 18A to 18C illustrate only the left side of the fixed plate SPL for convenience of illustration, it will be understood that a part corresponding to the right side of the fixed plate SPL may have the structure substantially the same as the structure of the structure at the left side of the fixed plate SPL.

Hereinafter, any repetitive detailed description of components, which are the same as components described with reference to drawings described above, of components illustrated in FIGS. 18A to 18C will be omitted or simplified.

Referring to FIG. 18A, an embodiment of the connecting part CPPa may be connected to the display assembly PCR. The coupling support bar COB of the support plate SPT may be coupled to the connecting bar CTBa.

When the display device DD is in the inserting mode, the fixing pin CPN (or the body part PCY thereof) passing through the elastic body SMD and the tensile bar ETBa may compress the elastic body SMD and may be coupled to the connecting bars CTBa. In this mode, the elastic body SMD generates elastic force for restoring from the first state to the third state. The elastic force may be applied to the coupling support bar COB connected to the connecting bars CTBa. Accordingly, tensile force may be generated in the coupling part JPT connected to the coupling support bar COB and the display module DM connected to the coupling part JPT. The elastic force and the tensile force may be equivalent to each other. The distance between the connecting bar CTBa and the tensile bar ETBa may be defined as the fourth distance D4, in the inserting state of the display device DD.

Referring to FIGS. 18A and 18B, when a display device DDa is changed from the inserting mode to the spreading mode, the tensile bar ETBa, the moving plate MVP, the display assembly PCR connected to the moving plate MVP, and the connecting bars CTBa connected to the display assembly PCR may be moved.

The moving distance of the moving plate MVP and the moving distance of the display assembly PCR may be different from each other. Accordingly, a ratio of the moving distance of the connecting bar CTBa connected to the coupling support bar COB to the moving distance of the moving plate MVP may be about 2:1. Since the features of the moving distance of the moving plate MVP to the moving distance of the connecting bars CTBa is substantially the same as those described above with reference to FIGS. 12A and 12B, any repetitive detailed description thereof will be omitted.

The moving distance of the tensile bar ETBa and the moving distance of the connecting bars CTBa may be equal to each other. The moving distance of the tensile bar ETB described with reference to FIGS. 11B and 12B and the moving distance of the connecting bars CTB may be identically applied to the moving distance of the tensile bar ETBa and the moving distance of the connecting bars CTBa illustrated in FIGS. 18A and 18B. The distance between the tensile bar ETBa and the connecting bar CTBa may be defined as a fifth distance D5, in the spreading mode of the display device DD.

The fourth distance D4 and the fifth distance D5 may be substantially equal to each other. As the fourth distance D4 in the inserting mode is equal to the fifth distance D5 in the spreading mode, the elastic bod SMD interposed between the tensile bar ETBa and the head part FSP may be in the first state. The elastic body SMD in the inserting mode or the spreading mode may be maintained compressed.

Referring to FIGS. 18B and 18C, when the furrow is formed in the display module DM and the coupling part JPT, the tensile force of the display module DM and the coupling part JPT may be reduced. The tensile force applied to the coupling support bar COB connected to the coupling part JPT may be reduced. Accordingly, the equivalence between the elastic force and the tensile force may be broken. As illustrated in FIG. 18C, state of the elastic body SMD may become to the third state.

When the elastic body SMD becomes in the third state, the elastic body SMD may apply elastic force to the connecting bars CTBa in a direction parallel to the first direction DR1. The connecting bars CTBa may move in the first direction DR1 toward the tensile bar ETBa. The distance between the connecting bar CTBa and the tensile bar ETBa may be reduced. In an embodiment, for example, the connecting bars CTBa and the tensile bar ETBa may make contact with each other when the distance between the connecting bar CTBa and the tensile bar ETBa is reduced.

When the connecting bar CTBa moves in the first direction DR1 toward the tensile bar ETBa, the coupling support bar COB connected to the connecting bar CTB, the coupling part JPT connected to the coupling support bar COB, and the display module DM connected to the coupling part JPT may move in the first direction DR1. Accordingly, the furrow made in the display module DM and the coupling part JPT may be spread to be flat, such that the surface quality of the display device DD may be improved.

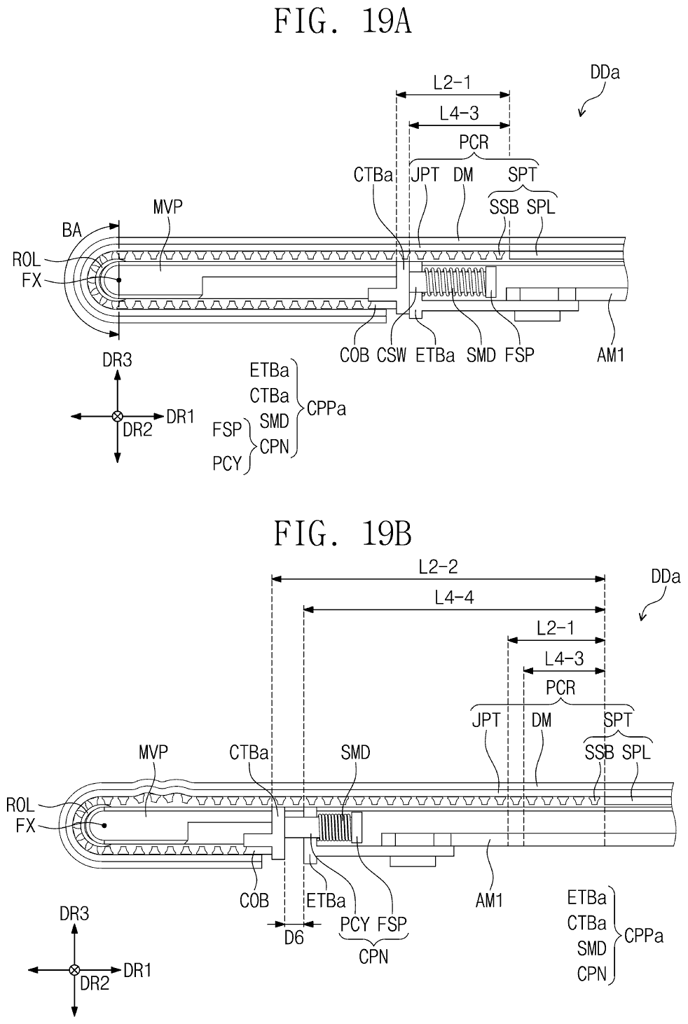

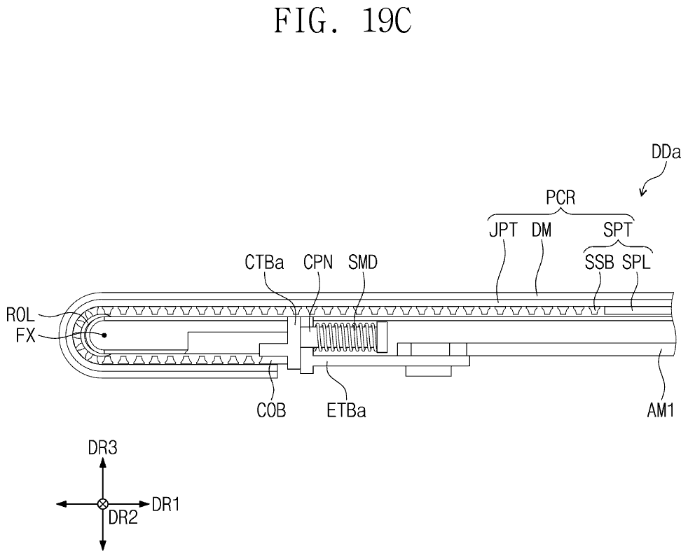

FIGS. 19A to 19C are views illustrating the display device according to an embodiment of the disclosure.

Particularly, FIG. 19A is a cross-sectional view illustrating a display device DDa in the inserting mode, and FIGS. 19B and 19C are cross-sectional views of the display device DDa in the spreading mode.

For the convenience of description, the display device DDa illustrated in FIGS. 19A to 19C will be described while focusing on the difference from the display device DDa illustrated in FIGS. 18A to 18C.

Referring to FIG. 19A, when the display device DDa is contracted, the tensile bar ETBa and the connecting bars CTBa may make contact with each other. The elastic body SMD interposed between the head part FSP and the tensile bar ETBa may be uncompressed. For example, the elastic body SMD may be in the third state.

When the elastic body SMD is in the normal state, the elastic body SMD may not apply the elastic force to the connecting bars CTBa. The elastic force may not act on the coupling support bar COB connected to the connecting bar CTBa, the coupling part JPT connected to the coupling support bar COB, and the display module DM connected to the coupling part JPT. Accordingly, the display module DM may be effectively prevented from being damaged due to elastic force.

Referring to FIGS. 19A and 19B, when the display device DDa is changed from a contracting state (or the inserting state) to an expanding state (or the spreading state), the moving distance of the connecting bar CTBa and the moving distance of the tensile bar ETBa may be different from each other.

The difference between the moving distance of the tensile bar ETB and the moving distance of the connecting bars CTB described with reference to FIGS. 16A and 16B will be identically applied to FIGS. 19A and 19B. A value obtained by subtracting the (2-1)-th length L2-1 from the (2-2)-th length L2-2 may be greater than a value obtained by subtracting the (4-3)-th length L4-3 from the (4-4)-th length L4-4.

The value obtained by subtracting the (4-3)-th length L4-3 from the (4-4)-th length L4-4 to the value obtained by subtracting the (2-1)-th length L2-1 from the (2-2)-th length L2-2 may be about 2:1.9.

As the moving distance of the connecting bar CTBa is greater than the moving distance of the tensile bar ETBa, the connecting bars CTBa and the tensile bar ETBa may be spaced apart from each other in the first direction DR1. The distance between the connecting bar CTBa and the tensile bar ETBa may be defined as a sixth distance D6, in the spreading state of the display device DDa.

Accordingly, the elastic body SMD interposed between the head part FSP and the tensile bar ETBa may be compressed. The variation in length of the elastic body SMD may be equal to the distance between the moving distance of the connecting bars CTBa and the moving distance of the tensile bar ETBa. The variation in length of the elastic body SMD may be equal to a sixth distance D6.

Referring to FIGS. 19B and 19C, in the spreading state, when the furrow is made in the display module DM and the coupling part JPT, the elastic body SMD may become in the third state. As the elastic body SMD becomes in the third state, the connecting bar CTBa may move toward the tensile bar ETBa. When the connecting bar CTBa moves toward the tensile bar ETBa, the coupling support bar COB connected to the connecting bar CTBa, the coupling part JPT connected to the coupling support bar COB, and the display module DM connected to the coupling part JPT may move in the first direction DR1. Accordingly, the furrow formed in the display module DM and the coupling part JPT may be spread to be flat.

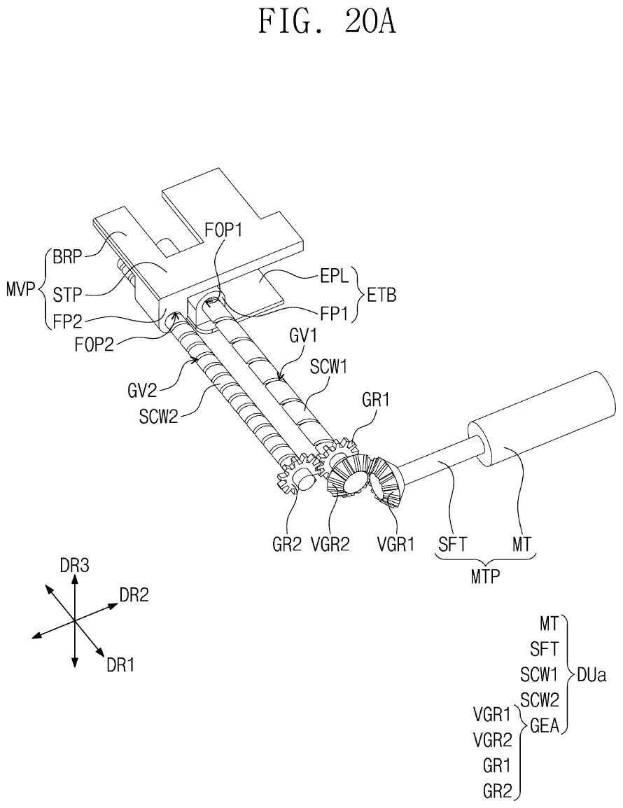

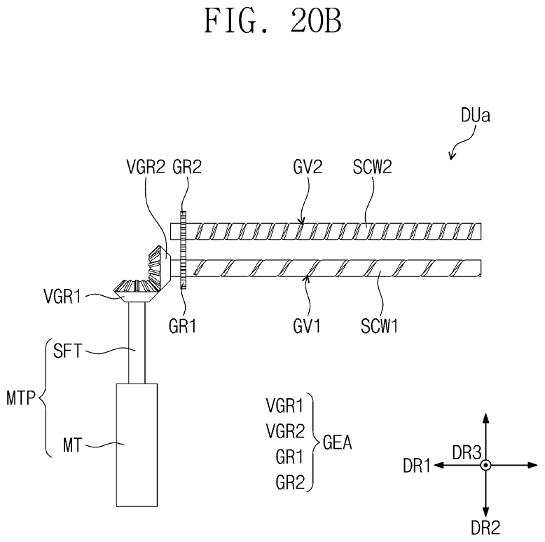

FIGS. 20A and 20B are views illustrating a driving unit according to an embodiment of the disclosure.

Particularly, FIG. 20A is a perspective view, and FIG. 20B is a plan view.

For the convenience of illustration and description, FIG. 20A illustrates a part of the tensile bar ETB and a part of the moving plate MVP.

The description about components illustrated in FIGS. 20A to 20B will be made by making reference to the above-description, and any repetitive detailed description of components, which are the same as components described with reference to drawings described above, of components illustrated in FIGS. 20A to 20B will be omitted or simplified.

Referring to FIG. 20A, an embodiment of a driving unit DUa may include a motor unit MTP to generate a rotational force, a first screw SCW1 coupled to the tensile bar ETB, a second screw SCW2 coupled to the moving plate MVP, and a gear assembly GEA to transmit the rotational force from the motor unit MTP to the first and second screws SCW1 and SCW2.

The motor unit MTP may include a motor MT and a shaft SFT extending from the motor MT in the second direction DR2. The motor MT may generate the rotational force. The shaft SFT extending from the motor MT may rotate about a rotation axis parallel to the second direction DR2, by the rotational force.

The tensile bar ETB may further include a first guide unit FP1. The first guide unit FP1 may be disposed on a top surface of the coupling plate EPL. The first screw SCW1 may be coupled to the tensile bar ETB. The first screw SCW1 may be coupled to the first guide unit FP1 of the tensile bar ETB. The first screw SCW1 may be inserted into a first guide opening FOP1 defined in the first guide unit FP1.

A first groove GV1 may be defined in an outer surface of the first screw SCW1. The first groove GV1 may extend in the first direction DR1 while surrounding the outer surface of the first screw SCW1. Although not illustrated, the first guide unit FP1 may further include a plurality of protrusions formed on an inner surface defining the first guide opening FOP1, and the protrusions may be inserted to correspond to the first groove GV1. Accordingly, when the first screw SCW1 rotates about the rotation axis parallel to the first direction DR1, the first guide unit FP1 may move in the first direction DR1 by the protrusions.

The moving plate MVP may further include a second guide unit FP2. The second guide unit FP2 may be disposed on a bottom surface of the stem part STP. The second screw SCW2 may be coupled to the moving plate MVP. The second screw SCW2 may be coupled to the second guide unit FP2 of the moving plate MVP. The second screw SCW2 may be inserted into a second guide opening FOP2 defined in the second guide unit FP2.

A second groove GV2 may be defined in an outer surface of the second screw SCW2. The second groove GV2 may extend in the first direction DR1 while surrounding the outer surface of the second screw SCW2. Although not illustrated, the second guide unit FP2 may further include a plurality of protrusions formed on an inner surface defining the second guide opening FOP2, and the protrusions may be inserted to correspond to the second groove GV2. Accordingly, when the second screw SCW2 rotates about the rotation axis parallel to the first direction DR1, the second guide unit FP2 may move in the first direction DR1 by the protrusions.

The gear assembly GEA may transmit the rotational force from the motor unit MTP to the first screw SCW1 and the second screw SCW2. The gear assembly GEA may include a first vertical gear VGR1, a second vertical gear VGR2, a first gear GR1, and a second gear GR2.

The first vertical gear VGR1 may be connected to one end of the shaft SFT. When the shaft SFT rotates about a rotation axis parallel to the second direction DR2, the first vertical gear VGR1 may rotate in the same direction as the shaft SFT.

The second vertical gear VGR2 may be connected to one end of the first screw SCW1. The second vertical gear VGR2 may be engaged with one end of the first vertical gear screw VGR1. When the first vertical gear VGR1 rotates, the second vertical gear VGR2 may rotate about the rotation axis parallel to the first direction DR1.

When the second vertical gear VGR2 rotates, the first screw SCW1 may rotate about the rotation axis parallel to the first direction DR1. When the first screw SCW1 rotates, the first guide unit FP1 may reciprocate in the first direction DR1 along the first screw SCW1. Accordingly, the tensile bar ETB may reciprocate in the first direction DR1.

The first gear GR1 may be connected to the first screw SCW1. The first gear GR1 may be interposed between the second vertical gear VGR2 and the first guide unit FP1. When the first screw SCW1 rotates, the first gear GR1 may rotate in the same direction as the first screw SCW1.

The second gear GR2 may be connected to the second screw SCW2. The second vertical gear GR2 may be connected to one end of the second screw SCW2. The second gear GR2 may be engaged with the first GR1. When the first gear GR1 rotates, the second gear GR2 may rotate about the rotation axis parallel to the first direction DR1. When the second gear GR2 rotates, the second screw SCW2 may rotate about the rotation axis parallel to the first direction DR1. When the second screw SCW2 rotates, the second guide unit FP2 may move in the first direction DR1 along the second groove GV2 defined in the outer surface of the second screw SCW2. Accordingly, the moving plate MVP may move in the first direction DR1.

When the rotational force is generated from the motor MT, the tensile bar ETB and the moving plate MVP may move in the first direction DR1. The moving distance of the tensile bar ETB and the moving distance of the moving plate MVP may be equal to each other.

In an embodiment, a pitch of the first groove GV1 defined in the first screw SCW1 and a pitch of the second groove GV2 defined in the second screw SCW2 may be different from each other. The pitch of the first groove GV1 may be greater than the pitch of the second groove GV2. When the first screw SCW1 and the second screw SCW2 rotate in equal revolutions per minute (RPM), the moving distance of the first guide unit FP1 may be greater than the moving distance of the second guide unit FP2. Accordingly, the ratio of the moving distance of the tensile bar ETB connected to the first guide unit FP1 to the moving distance of the moving plate MVP connected to the second guide unit FP2 may be about 1:1.9.

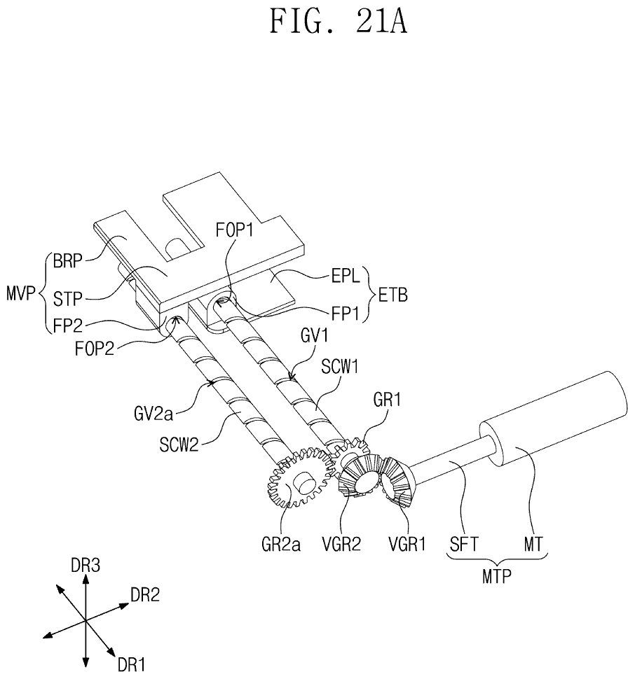

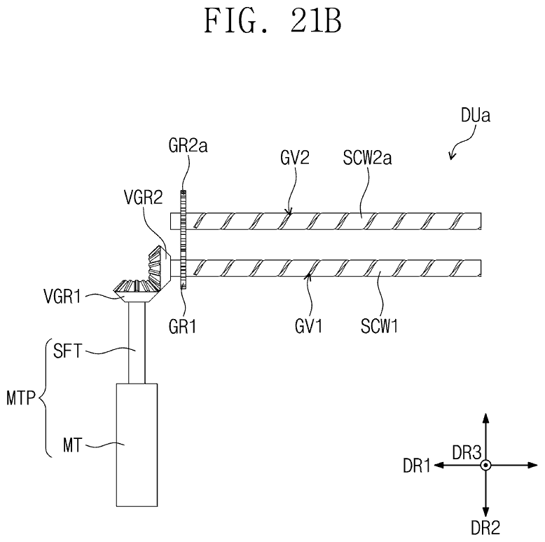

FIGS. 21A and 21B are views illustrating a driving unit according to an embodiment of the disclosure.

Particularly, FIG. 21A is a perspective view, and FIG. 21B is a plan view.

For the convenience of illustration and description, FIG. 21A illustrates a portion of the tensile bar ETB and a portion of the moving plate MVP.

The description about components illustrated in FIGS. 21A to 201 will be made by making reference to the above-description, and any repetitive detailed description of components, which are the same as components described with reference to drawings described above, of components illustrated in FIGS. 21A to 21B will be omitted or simplified.

Referring to FIGS. 21A and 21B, in an embodiment, the pitch of the first groove GV1 defined in the outer surface of the first screw SCW1 may be the same as the pitch of the second groove GV2a defined in the outer surface of the second screw SCW2a.

A radius of the first gear GR1 may be smaller than a radius of the second gear GR2a. A circumference of the first gear GR1 may be smaller than a circumference of the second gear GR2a. Accordingly, the number of gear teeth of the second gear GR2a may be greater than the number of teeth of the first gear GR1.

When the motor MT operates, the rotational amount of the second gear GR2a engaged with the first gear GR1 may be smaller than the rotational amount of the first gear GR1. In an embodiment, for example, the rotational amount of the second gear GR2a with respect to the rotational amount of the first gear GR1 may be about 1.9:1.

Accordingly, the moving distance of the tensile bar ETB connected to the first gear GR1 through the first screw SCW1 may be different from the moving distance of the moving plate MVP connected to the second gear GR2a through the second screw SCW2. The moving distance of the tensile bar ETB may be greater than the moving distance of the moving plate MVP. In an embodiment, for example, the moving distance of the tensile bar ETB to the moving distance of the connecting bars CTB may make the ratio of about 1.9:1.

As described above, according to an embodiment of the disclosure, as the elastic body is uncompressed while applying elastic force to the support bar, the coupling part, and the display module. The deformed part of the display assembly may be recovered to be flat by the elastic force. Accordingly, the surface quality of the display module may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display assembly including a first region on a plane defined by a first direction and a second direction crossing the first direction, and a second region extending from the first region, wherein the second region is disposed under the first region is in an inserting state, and a portion of the second region is on a same plane as the first region in a spreading state; and
an extending module disposed under the first region,
wherein the extending module includes:
a first part coupled to an end of the second region and extending in the second direction;
a second part disposed at a side of the first part in the first direction and extending in the second direction;
a fixing pin including a body part extending in the first direction and passing through the first part or the second part, and a head part disposed at an end of the body part; and
an elastic body interposed between the first part or the second part, through which the body part passes, and the head part, and
wherein a moving distance of the first part in the first direction is substantially equal to a moving distance of the second part in the first direction when a state of the display assembly is changed from the inserting state to the spreading state.

2. The display device of claim 1, wherein a state in which the elastic body is compressed is defined as a first state, and a state, in which the elastic body is relaxed than the first state, is defined as a second state, and
wherein the elastic body is in the first state when the display assembly is in the inserting state or the spreading state, and
wherein a first distance is defined as a distance between the first part and the second part when the display assembly is in the inserting state, and
wherein a second distance is defined as a distance between the first part and the second part when the display assembly is in the spreading state, and
wherein the first distance and the second distance are substantially equal to each other.

3. The display device of claim 2, wherein the extending module further include a moving plate coupled to the display assembly, and
wherein the moving plate is interposed between the first region and the second region, and a ratio of a moving distance of the second part to a moving distance of the moving plate is about 1:2 when a state of the display assembly is changed from the inserting state to the spreading state.

4. The display device of claim 3, wherein the body part is coupled to the second part through the first part, and
wherein the elastic body is interposed between the head part and an opposite side of the first part.

5. The display device of claim 3, wherein
the body part is coupled to the first part through the second part,
the elastic body is interposed between the head part and a side of the second part, and
the side of the second part is defined as a side disposed further away from the side of the first part.

6. The display device of claim 3, wherein the extending module further include a driving unit coupled to the moving plate and the second part,
wherein the driving unit includes:
a motor which generates a rotational force;
a gear assembly which transmits the rotational force;
a first screw coupled to the second part to receive the rotational force from the gear assembly; and
a second screw coupled to the moving plate to receive the rotational force from the gear assembly, and
wherein the gear assembly includes:
a first vertical gear coupled to the motor;
a second vertical gear coupled to the first screw and engaged with the first vertical gear to rotate about a rotation axis parallel to the first direction;
a first gear coupled to the first screw to rotate in a direction the same as a direction of the second vertical gear; and
a second gear coupled to the second screw and engaged with the first vertical gear to rotate about a rotation axis parallel to the first direction.

7. The display device of claim 6, wherein a number of gear teeth of the first gear is smaller than a number of gear teeth of the second gear.

8. The display device of claim 6, wherein a length of a first groove defined along an outer surface of the first screw is shorter than a length of a second groove defined along an outer surface of the second screw.

9. The display device of claim 3,
wherein the extending module further include a driving unit coupled to the moving plate and the second part,
wherein the driving unit includes:
a main plate;
a first arm coupled to a bottom surface of the main plate, wherein the first arm is unfolded or folded in the first direction; and
a second arm coupled to a bottom surface of the main plate, wherein the second arm is symmetrical to the first arm about the second direction, and the second arm is unfolded or folded in the first direction.

10. A display device comprising:
a display assembly including a first region on a plane defined by a first direction and a second direction crossing the first direction, and a second region extending from the first region, wherein the second region is disposed under the first region in an inserting state, and a portion of the second region is on a same plane as the first region in a spreading state; and
an extending module disposed under the first region,
wherein the extending module includes:
a first part coupled to an end of the second region and extending in the second direction;
a second part disposed at a side of the first part in the first direction and extending in the second direction;
a fixing pin including a body part extending in the first direction and passing through the first part or the second part, and a head part disposed on an end of the body part; and
an elastic body interposed between the first part or the second part, through which the body part passes, and the head part, and
wherein a moving distance of the first part in the first direction is greater than a moving distance of the second part in the first direction, when a state of the display assembly is changed from the inserting state to the spreading state.

11. The display device of claim 10, wherein a state in which the elastic body is compressed is defined as a first state, and a state, in which the elastic body is relaxed than the first state, is defined as a second state, and
wherein the elastic body is in the second state when the display assembly is in the inserting state, and the elastic body is in the first state when the display assembly is in the spreading state.

12. The display device of claim 11, wherein a first distance is defined as a distance between the first part and the second part when the display assembly is in the inserting state, and
wherein a second distance is defined as a distance between the first part and the second part when the display assembly is in the spreading state, and
wherein the second distance is greater than the first distance.

13. The display device of claim 12, wherein the extending module further includes a moving plate coupled to the display assembly,
wherein the moving plate is interposed between the first region and the second region, and
wherein two times a moving distance of the moving plate is greater than a moving distance of the second part, and
wherein a ratio of a sum of a moving distance of the second part and a decreased length of the elastic body to a moving distance of the moving plate is about 1:2 when the state of the display assembly is changed from the inserting state to the spreading state.

14. The display device of claim 13, wherein the body part is coupled to the second part through the first part, and
wherein the elastic body is interposed between the head part and an opposite side of the first part.

15. The display device of claim 13, wherein
the body part is coupled to the first part through the second part,
the elastic body is interposed between the head part and a side of the second part, and
the side of the second part is defined as a side disposed further away from the side of the first part.

16. The display device of claim 13, wherein the extending module further include a driving unit coupled to the moving plate and the second part,
wherein the driving unit includes:
a motor which generates a rotational force;
a gear assembly which transmits the rotational force;
a first screw coupled to the second part to receive the rotational force from the gear assembly; and
a second screw coupled to the moving plate to receive the rotational force from the gear assembly, and
wherein the gear assembly includes:
a first vertical gear coupled to the motor;
a second vertical gear coupled to the first screw and engaged with the first vertical gear to rotate about a rotation axis parallel to the first direction;
a first gear coupled to the first screw to rotate in a direction the same as a direction of the second vertical gear; and
a second gear coupled to the second screw and engaged with the first vertical gear to rotate about a rotation axis parallel to the first direction.

17. The display device of claim 16, wherein a number of gear teeth of the first gear is smaller than a number of gear teeth of the second gear.

18. The display device of claim 16, wherein a length of a first groove defined along an outer surface of the first screw is smaller than a length of a second groove defined along an outer surface of the second screw.

19. The display device of claim 13, wherein the extending module further include a driving unit coupled to the moving plate and the second part,
wherein the driving unit includes:
a main plate;
a first arm coupled to a bottom surface of the main plate, wherein the first arm is extended or folded in the first direction; and
a second arm coupled to a bottom surface of the main plate,
symmetrical to the first arm about the second direction, wherein the second arm is extended or folded in the first direction.

20. An electronic device comprising:
a display device, wherein the display device comprising,
a display assembly including a first region on a plane defined by a first direction and a second direction crossing the first direction, and a second region extending from the first region, wherein the second region is disposed under the first region is in an inserting state, and a portion of the second region is on a same plane as the first region in a spreading state; and
an extending module disposed under the first region,
wherein the extending module includes:
a first part coupled to an end of the second region and extending in the second direction;
a second part disposed at a side of the first part in the first direction and extending in the second direction;
a fixing pin including a body part extending in the first direction and passing through the first part or the second part, and a head part disposed at an end of the body part; and
an elastic body interposed between the first part or the second part, through which the body part passes, and the head part, and
wherein a moving distance of the first part in the first direction is substantially equal to a moving distance of the second part in the first direction when a state of the display assembly is changed from the inserting state to the spreading state.
